(19) United States
(12) Patent Application Publication
(10) Pub. No.: US 2025/0053781 A1
(43) Pub. Date: Feb. 13, 2025

(54) CONVOLUTIONAL NEURAL NETWORK MODEL-BASED ARC FAULT DETECTION

(71) Applicant: The University of North Carolina at Charlotte, Charlotte, NC (US)

(72) Inventors: Tiefu ZHAO, Charlotte, NC (US); Kamal Chandra PAUL, Monroe, NC (US); Yao WANG, Tianjin (CN)

(21) Appl. No.: 18/799,083

(22) Filed: Aug. 9, 2024

Related U.S. Application Data
(60) Provisional application No. 63/531,659, filed on Aug. 9, 2023.

(51) Int. Cl. G06N 3/045; G01R 31/08; G06N 3/096

(52) U.S. Cl. CPC G06N 3/045; G01R 31/088; G06N 3/096

(57) ABSTRACT

An apparatus obtains an input signal representative of a current passing through a first circuit and applies the input signal to one or more input nodes of a second circuit configured according to a convolutional neural network model. The apparatus drives one or more output nodes of the second circuit according to a detection by the convolutional neural network model of an arc fault in the current passing through the first circuit. The one or more output nodes are driven to either a first value indicative of an absence of the detection of the arc fault in the current passing through the first circuit, or a second value indicative of the detection of the arc fault in the current passing through the first circuit. A switch through which the current passes remains closed in response to the first value and opens in response to the second value.

### CROSS-REFERENCE TO RELATED APPLICATIONS

This application for patent claims priority to and the benefit of provisional patent application No. 63/531,659 entitled “ArcNet-Lite: Lightweight Deep Neural Network for Real-Time Series AC Arc Fault Protection” filed in the United States Patent and Trademark Office on Aug. 9, 2023, the entire content of which is incorporated herein by reference as if fully set forth below in its entirety and for all applicable purposes.

### TECHNICAL FIELD

This disclosure relates generally to arc fault detection, and more specifically, to convolutional neural network model-based arc fault detection.

### INTRODUCTION

Arc fault is characterized as a luminous discharge of electricity, generally between two conductors. By way of example, the discharge may bridge a gap between two tips of a closely spaced single conductor (e.g., where the gap may be caused by a breakage or severing of the conductor) or may bridge a gap between two parallel spaced-apart conductors (e.g., where electrical insulation was accidentally removed from parallel insulated conductor wires in a Romex™ cable (also referred to as a nonmetallic sheathed cable)). In the context of power distribution, wire conductors found in homes, businesses, and industrial settings are referred to by three names: a live wire (also referred to as line, hot, positive, or mains), a neutral wire (i.e., the wire that provides a return path to a source of electrical energy coupled between the live and neutral wires), and a ground wire (e.g., an earth ground). Arcs generally, but not always, bridge a gap between two bare wires. The gap may be caused by a loose connection of the wire to its termination (e.g., where an electrical plug is inserted and loosely captured within an old and/or worn-out receptacle), or where a screw capturing a wire is not sufficiently tightened. In other examples, the insulation surrounding a wire may have broken down due to age and may cither no longer provide its design insulation properties or may have become brittle and lost its flexibility, thereby cracking and being chipped away from the wire it surrounds. In other examples, the insulation surrounding the wires may be penetrated by an external intrusion (e.g., a piercing of) the insulation by for example, a nail, staple, or drywall screw inadvertently being driven through the insulation. In some cases, wires with adequate insulation in a cable may be brought too close together due to the cable being pinched or bent with too small of a radius.

The luminous discharge of energy may elevate the temperature in and around the arc by more than 5000 degrees (Celsius) and that heat may result in an electrical fire hazard. Such a temperature increase may occur even with a current of only 3 A to 12 A, for example. Arc faults may cause property damage, personal injury, or even death. In the United States arc fault is considered one of the prominent reasons for residential fire hazards.

In one study conducted by the Zebra, out of 1500 responses, 36.3% of fire hazards were alleged to be caused by electrical problems. According to the Industrial Safety and Hygiene News, over 30,000 arc flash incidents occur per year in the United States, leading to more than 400 fatalities, 7,000 burn injuries, and 2,000 hospitalizations each year.

To maintain safety from the electric fire hazard due to arc fault, the International Electrotechnical Commission (IEC), National Electrical Code (NEC), and Underwriters Laboratories (UL) have established standards for arc fault detection for household appliances. In the United States, it has been mandatory to use an arc fault circuit interrupter (AFCI) or arc fault detection devices (AFDD) for certain household loads since 2002. Scientists and engineers are continually researching and testing methods and apparatus that may improve the detection of arc faults.

### BRIEF SUMMARY OF SOME EXAMPLES

The systems, methods, and devices of this disclosure each have several innovative aspects, no single one of which is solely responsible for the desirable attributes disclosed herein.

In one example, an apparatus is described. The apparatus includes one or more memories and one or more processors coupled to the one or more memories. The one or more processors are configured to, individually or collectively, based at least in part on information stored in the one or more memories: obtain an input signal representative of a current passing through a first circuit, apply the input signal to one or more input nodes of a second circuit, different from the first circuit, and configured according to a convolutional neural network model, and drive one or more output nodes of the second circuit according to a detection by the convolutional neural network model of an arc fault in the current passing through the first circuit, the one or more output nodes driven to: a first value indicative of an absence of the detection of the arc fault in the current passing through the first circuit, or a second value indicative of the detection of the arc fault in the current passing through the first circuit.

In one example, a method at an apparatus is described. The method includes obtaining an input signal representative of a current passing through a first circuit, applying the input signal to one or more input nodes of a second circuit, different from the first circuit, and configured according to a convolutional neural network model, and driving one or more output nodes of the second circuit according to a detection by the convolutional neural network model of an arc fault in the current passing through the first circuit, the one or more output nodes driven to: a first value indicative of an absence of the detection of the arc fault in the current passing through the first circuit, or a second value indicative of the detection of the arc fault in the current passing through the first circuit.

In one example, an apparatus is described. The apparatus includes means for obtaining an input signal representative of a current passing through a first circuit; means for applying the input signal to one or more input nodes of a second circuit, different from the first circuit, and configured according to a convolutional neural network model; and means for driving one or more output nodes of the second circuit according to a detection by the convolutional neural network model of an arc fault in the current passing through the first circuit, the one or more output nodes driven to: a first value indicative of an absence of the detection of the arc fault in the current passing through the first circuit, or a second value indicative of the detection of the arc fault in the current passing through the first circuit.

Details of one or more implementations of the subject matter described in this disclosure are set forth in the accompanying drawings and the description below. Other features, aspects, and advantages will become apparent from the description, the drawings, and the claims. Note that the relative dimensions of the following figures may not be drawn to scale.

### BRIEF DESCRIPTION OF THE DRAWINGS

FIG. 1 is a schematic illustration of an example of a premises electrical distribution system according to some aspects of the disclosure.

FIG. 2 is a schematic diagram of a data collection system according to some aspects of the disclosure.

FIG. 3 depicts five graphs of normalized current versus time for five different load types according to some aspects of the disclosure.

FIG. 4 is a T-Distributed Stochastic Neighbor Embedding (T-SNE) visualization of normal current data and arc fault current data in the frequency domain according to some aspects of the disclosure.

FIG. 5 is an exemplary convolutional neural network model according to some aspects of the disclosure.

FIGS. 6A, 6B, 6C, 6D, and 6E are illustrations describing four convolutional neural network building blocks according to some aspects of the disclosure.

FIG. 7 is a schematic representation of a framework of a teacher-student knowledge distillation model according to some aspects of the disclosure.

FIG. 8A is a schematic representation of a teacher convolutional neural network model according to some aspects of the disclosure.

FIG. 8B is a schematic representation of a student convolutional neural network model according to some aspects of the disclosure.

FIG. 9 is a block diagram illustrating an example of a hardware implementation of an apparatus employing one or more processing systems according to some aspects of the disclosure.

FIG. 10 is a flow chart illustrating an example process at an apparatus in accordance with some aspects of the disclosure.

Like reference numbers and designations in the various drawings indicate like elements.

### DETAILED DESCRIPTION

The detailed description set forth below in connection with the appended drawings is directed to some particular examples for the purpose of describing innovative aspects of this disclosure. It is intended as a description of various configurations and is not intended to represent the only configurations in which the concepts described herein may be practiced. A person having ordinary skill in the art will readily recognize that the teachings herein can be applied in a multitude of different ways. The described examples can be implemented in any device, system, or network that is capable of protecting power distribution networks of any size.

The detailed description includes specific details for the purpose of providing a thorough understanding of various concepts. However, it will be apparent to persons having ordinary skill in the art that these concepts may be practiced without these specific details. In some examples, well-known structures and components are shown in block diagram form in order to avoid obscuring such concepts.

While aspects and examples are described in this application by illustration to some examples, persons having ordinary skill in the art will understand that additional implementations and use cases may come about in many different arrangements and scenarios. Innovations described herein may be implemented across many differing platform types, devices, systems, shapes, sizes, and packaging arrangements. For example, aspects and/or uses may come about via integrated chip examples and other non-module-component-based devices. While some examples may or may not be specifically directed to use cases or applications, a wide assortment of applicability of described innovations may occur. Implementations may range a spectrum from chip-level or modular components to non-modular, non-chip-level implementations and further to aggregate, distributed, or original equipment manufacturer (OEM) devices or systems incorporating one or more aspects of the described innovations. In some practical settings, devices incorporating described aspects and features may also necessarily include additional components and features for implementation and practice of claimed and described examples. For example, transmission and reception of wireless signals necessarily includes a number of components for analog and digital purposes (e.g., hardware components including antenna, radio frequency (RF)-chains, power amplifiers, modulators, buffer, processor(s), interleaver, adders/summers, etc.). It is intended that innovations described herein may be practiced in a wide variety of apparatus, components, systems, end-user devices, etc. of varying sizes, shapes, and constitution.

The various concepts presented throughout this disclosure may be implemented across a broad variety of electrical systems, system architectures, and electrical and/or power distribution standards.

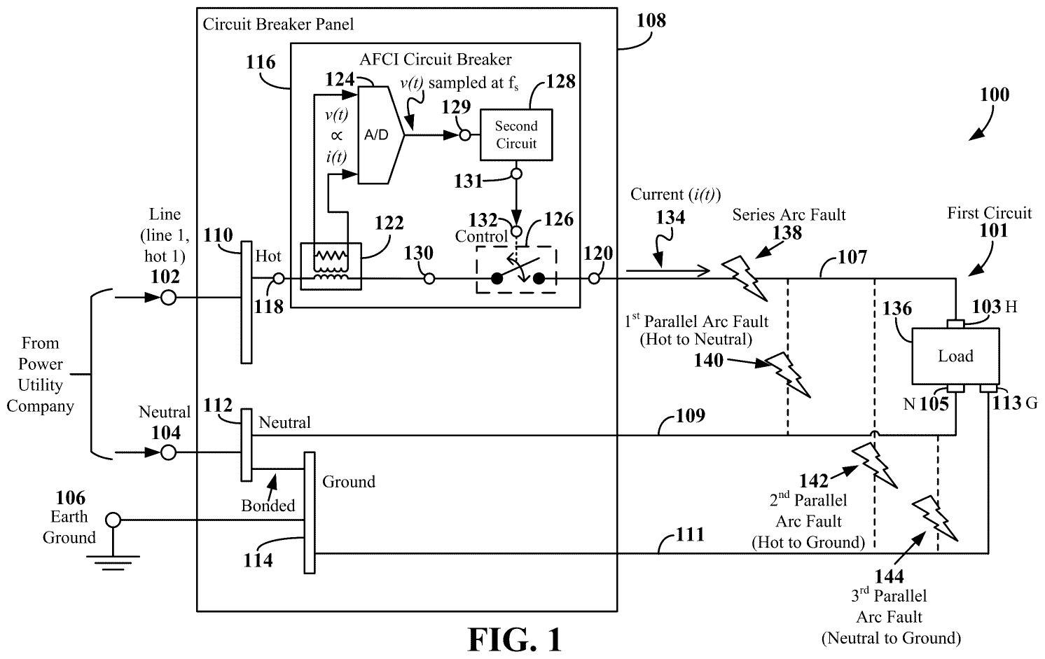

Referring now to FIG. 1, as an illustrative example without limitation, a schematic illustration of an example of a premises electrical distribution system 100 according to some aspects of the disclosure is presented. As used herein, a premises may include, but is not limited to, a house or any building and may include associated land and outbuildings.

The premises electrical distribution system 100 depicted in FIG. 1 is representative of a 120-volt single-phase system that may serve a premises. In one example, the premises may be a household. Persons having ordinary skill in the art will recognize that most households are supplied with either a 120-volt single-phase electrical system (referred to herein as a 120-volt service) or a 240-volt split-phase electrical system (referred to herein as a 240-volt service). The 120-volt service may be fed from a power utility company by two wires, often referred to as line 1 (or hot 1) and neutral, where there are 120 volts between line 1 and neutral. The 240-volt service may be fed from the power utility company by three wires, often referred to as line 1 (or hot 1), line 2 (or hot 2), and neutral, where the voltage between line 1 and neutral is 120 volts, the voltage between line 2 and neutral is 120 volts, and the voltage between line 1 and line 2 is 240 volts because line 1 and line 2 are 180 degrees out of phase with each other. In both the 120-volt service and the 240-volt service, an earth ground (similar to the earth ground 106) is “bonded” (i.e., connected) to the neutral at the served premises, typically in the service panel of the premises. The service panel may be a steel (or other material) box with a hinged door on its front. The hinged door provides access to the set/reset levers of all the circuit breakers in the service panel. As used herein, the service panel may be referred to as a circuit breaker panel 108. The circuit breaker panel 108 receives line 1, or line 1 and line 2, and neutral from the power utility company. Industrial premises may be fed with three-phase power (not shown), where each of the three lines of the three-phase power is 120 degrees out of phase with the other lines. In all cases, each line (line 1, line 2, and the three lines of the three-phase system) may be protected by a fuse, circuit breaker, or circuit breaker-type apparatus.

The 120-volt service may be referred to as 110, 115, 120, or 125 volts and may be distributed via one or more electrical circuits, such as the exemplary and non-limiting first circuit 101 of FIG. 1, throughout a premises. The 120-volt service may be distributed thought a premises via the premises wiring system/network (e.g., within the walls of a premises) and may feed built-in components/appliances such as lighting and dishwashing machines and are also presented at electrical outlets around the premises for plug-in items (e.g., televisions, lamps, computers, electrical extension cords, electrical power strips (e.g., an extension cord with multiple outlets) to name a few). The 240-volt service may be referred to as 220, 230, 240, or 250 volts. It may also be distributed via one or more electrical circuits throughout a premises, similar to the first circuit 101, but instead of the load 136 being coupled across the first conductive wire 107 (e.g., the line 1) and the second conductive wire 109 (e.g., the neutral) the load 136 may be coupled across the first conductive wire 107 (e.g., the line 1) and a fourth conductive wire (not shown) (e.g., the line 2, having a same voltage magnitude as the line 1 with a phase that is 180 out of phase with that of line 1). It may typically be built into the premises' wiring system and/or accessed via one or more dedicated outlets. The 240-volt service may be used for larger (e.g., in terms of power used) built-in appliances like central air conditioning units and electric ovens or larger plug-in appliances like clothes dryers and electric vehicle charging equipment.

As stated, FIG. 1 presents a 120-volt single-phase supply system for case of explanation and illustration and not limitation. All features described herein are applicable to, but not limited to, 120-volt single phase, 240-volt split phase, three-phase power supply networks and systems, and any electrical system that a fuse, circuit breaker, or circuit breaker type apparatus may protect. Although described herein using examples that employ alternating current (AC), aspects described herein are also applicable in examples that employ direct current (DC).

In the example of FIG. 1, the power supplied by a power utility company is coupled to a first terminal 102 (i.e., a terminal that serves a wire carrying voltage (e.g., line 1, hot 1)) and a second terminal 104 (i.e., a terminal that serves a wire serving as the neutral line in the premises).

The first terminal 102 is coupled to a first bus bar 110 (e.g., line 1 bus bar, hot 1 bus bar). The second terminal 104 is coupled to a second bus bar 112 (e.g., neutral bus bar). In the example of FIG. 1, a first terminal 118 of an arc fault circuit interrupter (AFCI) circuit breaker 116 (depicted for exemplary and non-limiting purposes) is coupled to the first bus bar 110. Although depicted with the AFCI circuit breaker 116, in general, the circuit breaker panel 108 may include one or more AFCI circuit breakers, ground fault circuit interrupter (GFCI) circuit breakers, and/or standard circuit breakers (without AFCI or GFCI capabilities, functions, or circuits). In some scenarios, standard circuit breakers may be used on a circuit in which an outlet coupled to the circuit is an AFCI and/or a GFCI outlet.

The first terminal 102 may be coupled to the first bus bar 110 within a circuit breaker panel 108. The second terminal 104 may be coupled to the second bus bar 112 (also referred to as the neutral bus bar herein), within the circuit breaker panel 108. An earth ground 106 may be coupled to a ground bus bar 114 within the circuit breaker panel 108. In most applications, the ground bus bar 114 is bonded (e.g., directly connected) to the second bus bar 112 within the circuit breaker panel 108, as shown in FIG. 1.

The AFCI circuit breaker 116 (and other types of circuit breakers and/or fuses (not shown)) may be included within the circuit breaker panel 108. A simplified block diagram of the AFCI circuit breaker 116 is depicted in FIG. 1 for illustrative and non-limiting purposes. A first terminal 118 of the AFCI circuit breaker 116 is coupled to the first bus bar 110. A second terminal 120 of the AFCI circuit breaker 116 is coupled to a first circuit 101 as depicted in FIG. 1. In the simplified illustration of FIG. 1, the first conductive wire 107 may couple the second terminal 120 of the AFCI circuit breaker 116 at a first end and to a hot terminal 103 of a load 136 at a second end. A second conductive wire 109 may couple the neutral terminal 105 of the load 136 to the second bus bar 112 within the circuit breaker panel 108. A third conductive wire 111 may couple the ground terminal 113 of the load 136 to the ground bus bar 114 within the circuit breaker panel 108.

The first conductive wire 107, the second conductive wire 109, and the third conductive wire 111 are often made of copper and are usually the same gauge (i.e., diameter). Other conductive materials like aluminum have also been used as conductive wiring. In some examples, the first conductive wire 107 and the second conductive wire 109 are insulated wires; their insulation may be made of, for example, a flexible polyvinyl chloride (PVC). In some examples, the third conductive wire 111 may be an insulated wire or a bare wire. The insulation may be color-coded: black for hot wires, white for neutral wires, and, if insulated, green for ground wires (otherwise, the ground wires may be bare copper wires). In some applications, the first conductive wire 107 (insulated), the second conductive wire 109 (insulated), and the third conductive wire 111 (insulated or bare) are bundled together and sheathed within a tube made of a non-conductive material, such as flexible nylon. An example of a nonmetallic sheathed cable is known as Romex™ cable, where Romex™ is a trademark of the Southwire Company. The bundled and sheathed conductors are referred to as a cable herein; however, any two or more wires bundled together (e.g., by non-conductive wire ties or sheathing) may be referred to as a cable herein. In older construction (such as pre-World War 1), wires protected by a flexible cloth insulated sleeving, sometimes cotton saturated with asphalt or rubber, can still be found.

There may be other components, such as switches (not shown), in series with the second terminal 120 of the AFCI circuit breaker 116, the first conductive wire 107, and the hot terminal 103 of the load 136. Furthermore, for example, and without limitation, other loads (not shown) may be coupled in parallel with the load 136, between/across the first conductive wire 107 and the second conductive wire 109.

According to some aspects, the AFCI circuit breaker 116 may include a current sensor circuit, referred to herein as a current sensor 122. The current sensor 122 may be any sensor, device, or apparatus that may provide a voltage waveform in the time domain (e.g., v(t)) that is proportional to the current 134 (i(t)) flowing through the AFCI circuit breaker 116. Any sensor, device, or apparatus, passive and/or active, that senses the current 134 (i(t)) flowing from the first terminal 118 to the second terminal 120 or from the second terminal 120 to the first terminal 118 (while the switch 126 is in a closed state) and produces a voltage (v(t)) proportional to the current 134 (i(t)) in real or near-real time may serve as the current sensor 122 and is within the scope of the disclosure.

For example, in the illustration of FIG. 1, the current sensor 122 is depicted as a transformer terminated with a resistor for explanatory and non-limiting purposes. Such a current sensor circuit may be referred to as a current transformer. The current transformer is a passive device that transforms the current 134 (i(t)) flowing between the first terminal 118 and the second terminal 120 (when switch 126 is closed) into a voltage waveform (v(t)) in the time domain. The amplitude of the voltage waveform (v(t)) developed across the resistor (shown in the exemplary illustration) may provide an accurate representation of the current 134 (i(t)) flowing through the current transformer.

According to some aspects, the AFCI circuit breaker 116 may include an analog-to-digital converter circuit, referred to herein as the A/D converter 124. The voltage waveform (v(t)) (an analog waveform) that is proportional to the current 134 (i(t)) may be converted to a digital waveform by the A/D converter 124. The A/D converter 124 may obtain the voltage waveform (v(t)) from the current sensor 122. The A/D converter 124 may convert the analog voltage waveform to a digital voltage waveform by sampling the analog voltage waveform at a predetermined sampling rate, also known as a sampling frequency (fₛ). The predetermined sampling frequency determines how many samples are taken from the continuous analog voltage waveform per second. According to some aspects, the sampling frequency may be selected to avoid unwanted lower-frequency components in the sampled data (referred to as aliasing). Other criteria for choosing the sampling frequency and other circuits for performing the analog-to-digital conversion are within the scope of the disclosure.

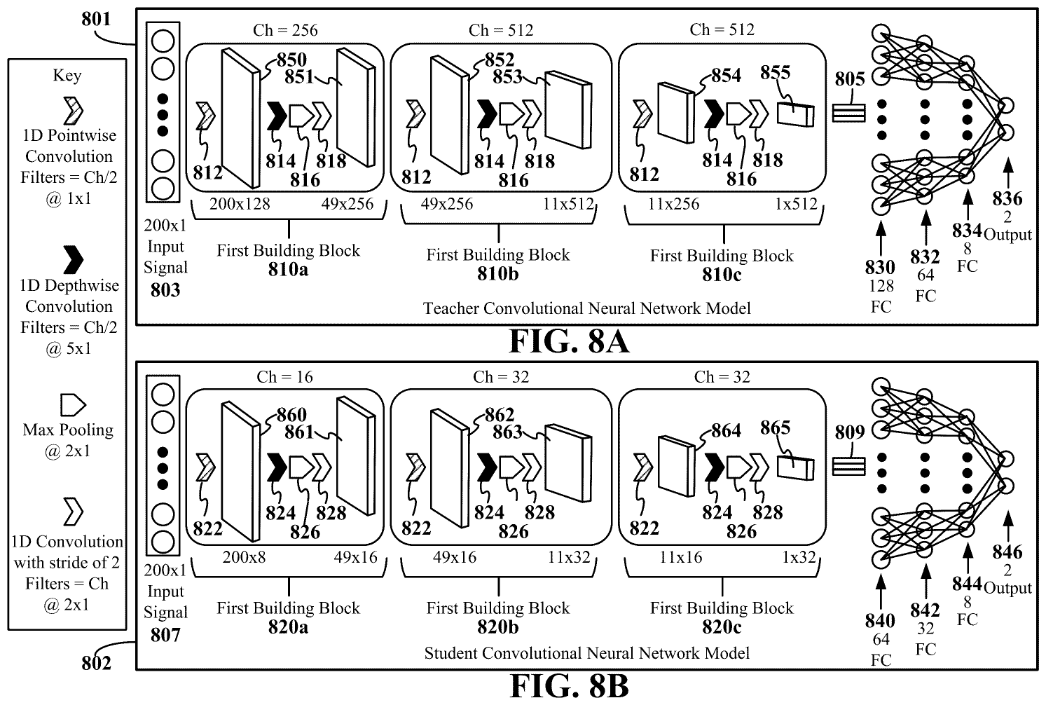

According to some aspects, the AFCI circuit breaker 116 may include a second circuit 128 that may implement a convolutional neural network model. According to some aspects, the convolutional neural network model may be optimized for embedded hardware Two non-limiting examples of hardware that may be utilized to perform aspects exemplified herein are a Raspberry Pi 3B or 4B single-board computer manufactured by the Raspberry Pi Foundation, and an STM32 MCU 32-bit microcontroller integrated circuit manufactured by STMicroelectronics. By way of comparison, the STM32 may be a lower-level edge computing device compared to a Raspberry Pi; accordingly, the STM32 may have an advantage in terms of cost, while still being able to provide sufficient computational power to efficiently implement any aspect of the disclosure exemplified herein. According to some examples, the convolutional neural network model may be the student convolutional neural network model 802 of FIG. 8B.

In some examples, the second circuit 128 may include one or more memories (not shown to avoid cluttering the drawing) and one or more processors (not shown to avoid cluttering the drawing) (e.g., an STM32 MCU). The one or more memories may be coupled to the one or more processors. The one or more processors may be configured to (individually or collectively, based at least in part on information stored in the one or more memories) obtain an input signal representative of the current 134 (i(t)) passing through the first circuit 101.

The voltage waveform (v(t)) and the sampled version of the voltage waveform, may both be representative of the current 134 (i(t)) passing through the first circuit 101. In other words, obtaining the input signal representative of the current 134 (i(t)) passing through the first circuit 101 may be equivalent to (or may be satisfied by) obtaining the sampled version of the voltage waveform (v(t)).

As depicted in FIG. 1, the first circuit 101 may be different from the second circuit 128. Also, as illustrated in FIG. 1, the first circuit 101 may be configured external to the one or more processors (not shown) that may be included in the second circuit 128.

According to some aspects, the one or more processors may be configured to apply the input signal (e.g., the sampled voltage waveform) to one or more input nodes (represented by the input node 129) of the second circuit 128 (where the second circuit 128 may include the one or more processors). The second circuit 128 may be configured according to a convolutional neural network model.

According to some aspects, before considering the sampled voltage waveform as the input signal, the one or more processors may be configured to normalize the sampled voltage waveform. In some examples, the normalization may be according to a min-max normalization, also known as feature scaling. The min-max normalization process may rescale the sampled data values to a range between 0 and 1. Min-max normalization may be considered a linear transformation that uses the minimum and maximum values of the original data (the sampled and digitized v (t) signal) to preserve the relative order and distance of data points in the original data.

According to some aspects, before considering the normalized data as the input signal, the one or more processors may be configured to perform a Fast Fourier Transform (FFT) on the normalized data to convert the normalized data from the time domain to the frequency domain. The frequency domain data may be considered the input signal.

According to some aspects, before considering the normalized data as the input signal, the one or more processors may be configured to perform a time domain feature extraction, where the extracted features in the time domain may be considered the input signal.

According to some aspects, the one or more processors that may be included in the second circuit 128 may also be configured to drive one or more output nodes (represented by output node 131) of the second circuit 128 according to a detection by the convolutional neural network model of an arc fault in the current passing through the first circuit 101. According to some aspects, the one or more output nodes (represented by output node 131) may be driven to a first value indicative of an absence of the detection of the arc fault in the current 134 (i(t)) passing through the first circuit 101, or may be driven to a second value, different from the first value, indicative of the detection of the arc fault in the current 134 (i(t)) passing through the first circuit 101.

Returning to the second circuit 128, and the one or more output nodes of the second circuit 128 represented by the output node 131, according to some aspects, output node 131 may be coupled to a control port or terminal of a switch 126, such as an electronically controllable (e.g., electronically changed between a closed state and an open state) single pole single throw (SPST) switch. In some examples, the switch 126 may be configured as an NMOS SPST switch or some other type of solid-state SPST switch.

Accordingly, the one or more output nodes of the second circuit, represented by the output node 131 may be driven according to a detection by the convolutional neural network model of an arc fault in the current 134 (i(t)) passing through the first circuit 101. In some examples, the one or more output nodes may be driven to a first value indicative of an absence of the detection of the arc fault in the current 134 passing through the first circuit 101 (e.g., driven to a first value (e.g., 1) that indicates the current 134 is a normal or nominal current without any evidence of an arc fault). In some examples, the one or more output nodes may be driven to a second value indicative of the detection of the arc fault in the current 134 passing through the first circuit 101 (e.g., driven to a second value (e.g., 0) that indicates the current 134 is an abnormal or perturbed current that includes evidence of an arc fault). Of course, the value of 1 for the first value and the value of 0 for the second value may be reversed.

In response to the output node 131 being driven to the first value (or maintained at the first value) the switch 126 may change to a closed state or be maintained in a closed state. In response to the output node 131 being driven to the second value (or maintained at the second value) the switch 126 may change to an open state or be maintained in the open state. According to some aspects, in response to the switch 126 being changed from the closed state to the open state, the switch may be latched in the open state (i.e., locked in the open state) regardless of whether the arc fault detection continues. The switch 126 may be latched, for example, until a reset signal on a reset line (not shown) causes the switch 126 to be responsive again to any value presented at the output node 131 to drive the control port 132 or the switch 126.

Turning now to the load 136. There are, of course, a great number of types of loads. Four non-limiting examples of loads were considered in the context of this disclosure; namely, resistive (RE) loads, motor (MO) loads, power electronics-enabled and switched-mode power supply (PE&SMPS) loads, and gas discharge lamp (GDL) loads. Table I provides a brief description of these loads and the total numbers of samples of currents with arc fault signatures (e.g., Table I current type=arc) and currents without arc fault signatures (also referred to as normal currents herein) (e.g., Table I current type=normal).

TABLE I

| | | | Current | Total |
|---|---|---|---|---|
| Load Groups | Loads | Labels | Type | Samples |
| Resistive | Electrical heater, electric | 0 | Arc | 4219 |
| (RE) | iron, incandescent lamps, | 1 | Normal | 8456 |
| | electric kettle | | | |
| Motor | Capacitor start motor, | 2 | Arc | 1918 |
| (MO) | vacuum cleaner, corded | 3 | Normal | 4455 |
| | electric hand tool | | | |
| | (e.g., drill) | | | |
| Power | Switch-mode power | 4 | Arc | 2889 |
| electronics- | supply loads, dimmer | 5 | Normal | 4522 |
| enabled and | (thyristor type) | | | |
| switched-mode | | | | |
| power supply | | | | |
| (PE&SMPS) | | | | |
| Gas discharge | Halogen lamps, | 6 | Arc | 597 |
| lamp (GDL) | fluorescent lamps | 7 | Normal | 3095 |

| | |
|---|---|
| Total number of samples | 30151 |

The resistive loads may have a nearly sinusoidal load current. Examples of a resistive loads may be an electric heater and a toaster. Motor loads may have a high in rush current. Examples of motor loads may include a corded electric hand drill motor, a capacitor start motor, and a vacuum cleaner motor. Gas discharge lamp loads may include, but are not limited to, two load types; namely, fluorescent lamps and halogen lamps. Power electronics-enabled and switched-mode power supplies are both electronic power supplies that may convert electrical power efficiently. Power electronics power supplies may be used to generate clean power and transfer wireless power. Switched mode power supplies may use semiconductor switching technology to convert power from a DC or AC source to a DC load. They are commonly used in electronic equipment that requires a stable and efficient power supply, such as computers, televisions, and power amplifiers. Power electronics-enabled and switched-mode power supply loads may include thyristor-type electric lamp dimmers, and computers having a wider bandwidth due to harmonics.

Arc faults may be categorized as series arc faults or parallel arc faults. A series arc fault 138 may occur, in one example, when a conductive wire is terminated at a screw post, but the screw is not tightened properly. A series arc fault 138 may occur, in another example, when a conductive wire is severed but the contact between the two severed ends may remain intermittently. A parallel arc fault may occur in three ways. A first parallel arc fault 140 (referred to herein as a hot to neutral parallel arc fault) may happen when the insulation of one or both adjacent insulated hot and neutral conductive wires decays, is abraded away, or is otherwise compromised, allowing an arc to jump between the hot conductive wire (first conductive wire 107) and the neutral conductive wire (second conductive wire 109). A second parallel arc fault 142 may happen when the insulation of a hot conductive wire (first conductive wire 107) decays, is abraded away, or is otherwise compromised, allowing an arc to jump between the hot conductive wire (first conductive wire 107) and a bare ground wire (third conductive wire 111). If the ground wire is an insulated wire, the second parallel arc fault 142 may happen when the insulation of one or both adjacent insulated hot conductive wire (first conductive wire 107) and insulated ground conductive wire (third conductive wire 111) decays, is abraded away, or is otherwise compromised, again allowing an arc to jump between the hot conductive wire (first conductive wire 107) and the ground wire (third conductive wire 111). A third parallel arc fault 144 may happen when the insulation of a neutral conductive wire (second conductive wire 109) decays, is abraded away, or is otherwise compromised, allowing an arc to jump between the neutral conductive wire (second conductive wire 109) and a bare ground wire (third conductive wire 111). If the ground wire is an insulated wire, the third parallel arc fault 144 may happen when the insulation of one or both adjacent insulated neutral conductive wire (second conductive wire 109) and insulated ground conductive wire (third conductive wire 111) decays, is abraded away, or is otherwise compromised, again allowing an arc to jump between the neutral conductive wire (second conductive wire 109) and the ground wire (third conductive wire 111).

The first parallel arc fault 140, the second parallel arc fault 142, and the third parallel arc fault 144 may be characterized by a heavy current, making it easier to detect using a conventional circuit breaker. Recognition of the series arc fault 138, on the other hand, may be challenging and complicated due to the limitations of the series impedance and indistinctiveness of the arc features. As a result, the current amplitude (e.g., magnitude of the current 134 (i(t)) may not increase, but may instead decrease, with respect to the amplitude of current 134 without arcs (i.e., the normal, or nominal current in the absence of a series arc fault 138). Moreover, some residential loads, such as switched-mode power supply loads under normal conditions (without any arc fault), may draw a current that resembles an arc fault, often resulting in nuisance tripping of some AFCI circuit breakers. At least these characteristics make the series arc fault detection more challenging than parallel arc fault detection.

Conventional arc fault detection algorithms may include either time or frequency domain feature extraction techniques or sometimes a combination of both. Fast Fourier Transform (FFT), wavelet transform (WT), analysis of correlation, discrete wavelet transform (DWT), and chirp zeta transform (CZT) are some widely used traditional methods to detect series arc faults such as the series arc fault 138 illustrated in FIG. 1. However, conventional arc fault detection algorithms are associated with manual threshold selection, which is tricky and inconvenient. The manual (hand-adjusted) preset thresholds may cause nuisance tripping due to the changes in background noise or load conditions. The use of traditional AFCIs or arc fault detection devices (AFDDs) in the distribution system also yields poor arc fault detection accuracy.

Because of yielding a high classification accuracy, artificial intelligence (AI) and machine learning (ML) based arc fault detection algorithms have become a promising focus to researchers in recent years. Many different classification algorithms including support vector machine (SVM), particle swarm optimization in combination with self-organizing map neural network, recurrent neural network (RNN), learning vector quantization neural network (LVQ-NN), decision tree-based algorithm, random forest, backpropagation neural network, convolutional neural network, and bulky and/or complex convolutional neural network, with or without data preprocessing techniques, have been used for arc fault classification. Besides classifying series arc faults, some of the algorithms can classify the load types or load groups where the arc fault occurs. However, most of those methods used some sort of time domain, frequency domain, or both time domain and frequency domain data preprocessing techniques for feature extraction before feeding the data to the neural network models. Moreover, most of the just described models did not have a real-time application capability, meaning that runtime may be too high to be implemented in a commercial microcontroller unit (MCU).

One example used a convolutional neural network architecture (a convolutional neural network model) for series arc fault detection of a specific type of load. However, the example utilized a low sampling frequency of 2.5 kHz, which results in an inability to identify an arc fault signature in current signal (i.e., the current 134 flowing through the first circuit 101, in the parlance of FIG. 1. Moreover, the example relied upon a formation of a 2D input matrix, performed by point-by-point isometric mapping, which added a computational burden to the convolutional neural network model.

The formation of a 2D input matrix, performed by point-by-point isometric mapping, may be reduced to a ID time series for convolutional neural network model simplification.

The International Electrotechnical Commission (IEC) is an organization that develops and publishes international standards for electrical and electronic technologies, including power supplies. One IEC standard indicates that for a 230V power supply system, a recommended maximum break time is Is for 2.5 A load current and 120 ms for 63 A load current. For a 120V system, the recommended breaking time is Is for a 5 A load current and 140 ms for a 63 A load current.

An arc fault can happen at any time. For real-time operation, considering the data preprocessing time and data acquisition time, testing time, possible signaling delay time, and circuit breaking time, a preferred arc fault detection system should detect an arc fault in less than 16.67 ms for a 60 Hz power supply system, or less than 20 ms for a 50 Hz power supply system. If an arc fault detection model becomes so cumbersome that it takes more time in inference than data acquisition time in a real-time system, that arc fault detection model will miss a few subsequent samples while checking on a normal current sample (i.e., a current sample that does not include an arc fault signature). Those missed samples may equate to potential arc fault samples that may go unnoticed because of time and computational constraints.

Furthermore, a large-scale deep neural network models, which may achieve superior performance in classification problems in comparison to lesser-scale deep neural network models (e.g., because of over-parameterization and generalization capability), have computational complexity that requires more storage space and memory in comparison to the lesser-scale deep neural network models. In addition to this, if some primary features are extracted beforehand, the primary feature extraction further increases the computational burden associated with the model. This can pose a great challenge to the deployment of those models in commercial edge computing devices that have limited computing resources. Therefore, scientists and engineers have sought to build an efficient and lightweight deep neural network learning model for arc fault detection which may be implemented in one or more inexpensive processors with relaxed processing capability that do not require substantial memory and storage space to reliably and quickly detect arc faults in real-time with good accuracy.

Described herein are efficient and lightweight deep neural network models that may be built either using efficient building blocks such as a depthwise separable convolution block, a pointwise convolution block, or model compression and acceleration techniques such as parameter pruning and sharing, low-rank factorization and transferred compact convolutional filters.

When it comes to model compression and acceleration, knowledge distillation (KD) has gained increasing attention in the research community. Using the knowledge distillation method, knowledge from a larger and cumbersome network may be distilled into a smaller and simpler network. This gives the benefit of making the final model lightweight and efficient yet built upon the greater knowledge acquired from the larger and more cumbersome network.

Described herein is a series arc fault detection algorithm using a combination of a lightweight convolutional neural network model (e.g., architecture) and a teacher-student knowledge distillation technique. The model may detect an arc fault with high accuracy. The model may be optimized using a TensorFlow-Lite (TF-Lite) optimization tool and with a reduced binary size for easy implementation in a resource-limited edge device. The optimized model may be implemented in a Raspberry PI 4B or 3B device, for example, to evaluate the performance for practical and real-time operation.

Some aspects described herein include the development of an ultra-fast, lightweight, and efficient algorithm for detecting series arc faults using raw current as input. The algorithm may be referred to as ArcNet-Lite herein. The algorithm may employ the teacher-student knowledge distillation technique and a highly efficient convolutional neural network model. The architecture of the model may be designed using an efficient network architecture by avoiding a stringent bottleneck structure. The Knowledge distillation-based network compression technique may be applied to the model to obtain a deep model having the least possible computational burden without sacrificing accuracy. The disclosed model achieves an arc fault detection accuracy of 99.31%.

According to another aspect, a mixed precision system (16-bit and 32-bit floating points) may be used for training the model. The performance of the trained model may be boosted using the TensorFlow Lite (TF-Lite) optimization tool, which yields reduced binary size and lowers latency. The optimized model was implemented on a Raspberry PI 4B edge computing device (which has little computational complexity and power) and evaluated for its real-time performance. The result was an extremely low runtime (0.20 ms/sample) on the edge device.

MobileNet, developed by Google, is an example of a deep neural network architecture specifically designed for use on mobile and embedded devices with limited computational resources. One experimental network model was constructed based on the MobileNet architecture. The model was optimized using the TF-Lite tool and evaluated on a Raspberry PI 4B. It achieved an arc fault classification accuracy of 99.29%.

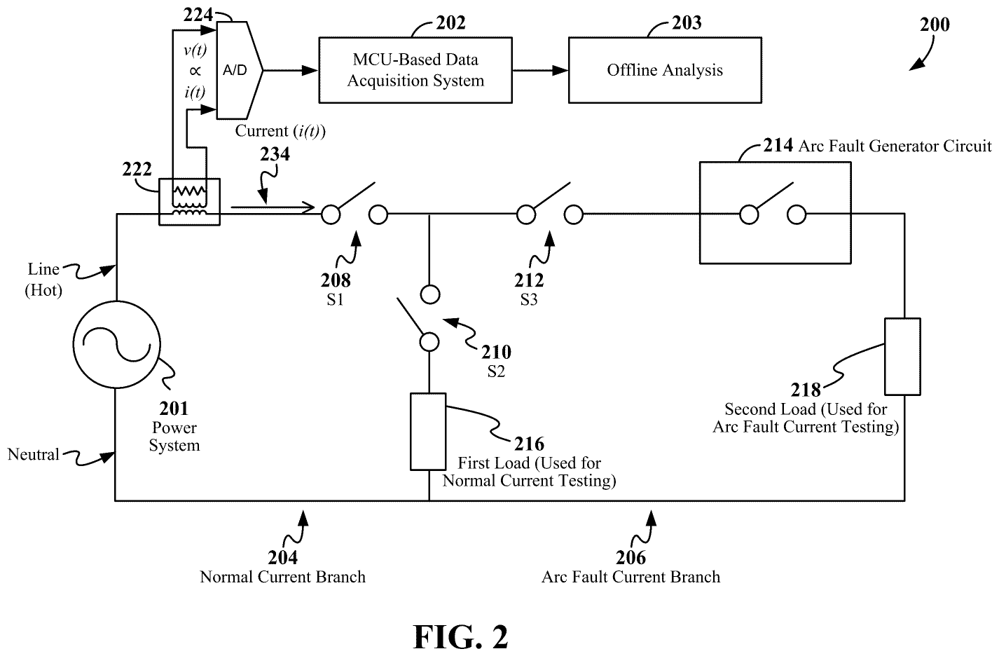

FIG. 2 is a schematic diagram of a data collection system 200 according to some aspects of the disclosure. The data was collected using a microcontroller unit (MCU)-based data acquisition circuit 202 as shown in FIG. 2. Although an analog-to-digital converter circuit 224 is depicted, the conversion of the analog voltage (v(t)) proportional to the current 234 (i(t)) flowing through the normal current branch 204 (with first switch 208 (S1) closed, second switch 210 (S2) closed, and third switch 212 (S3) open) or the arc fault current branch 206 (with first switch 208 (S1) closed, second switch 210 (S2) open, and third switch 212 (S3) closed) may occur in the analog-to-digital converter circuit 224 or in a similar converter circuit in the MCU-based data acquisition circuit 202 according to some aspects of the disclosure.

A current sensor 222 (similar to the current sensor 122 as shown and described in connection with FIG. 1) was used to sense the current 234 (i(t)). An arc fault generator circuit 214 having a stationary graphite electrode and a movable copper electrode was used to generate an arc in the arc fault current branch 206. Normal current samples were collected by substituting the loads in Table I (above) for the first load 216 (used for normal current branch testing) in the normal current branch 204 (established with the first switch 208 (S1) and the second switch 210 (S2) closed, while the third switch 212 (S3) is open). Arcing current samples were collected by substituting the loads in Table I for the second load 218 (used for arc fault current branch testing) in the arc fault current branch 206 (with the first switch 208 (S1) and the third switch 212 (S3) closed and the and the second switch 210 (S2) open or closed). The complete database contains a total of 30151 samples of 4 major load categories as shown in Table I.

Each sample represents one cycle of a 220 V, 50 Hz power system 201. The samples are low-frequency current which is collected following the IEC 62606 standard. Original data have a sampling frequency of 83.33 kHz, which is converted to 10 kHz for this research because a 10 kHz sampling rate was found to provide optimum arc fault detection performance. This leaves every sample as a one-dimensional (1D) time vector having a length of 200 data points. All the samples were normalized using a min-max normalization technique described above in connection with FIG. 1.

The arc current samples in this database were collected using the arc fault generator circuit 214 as well as a cable specimen (not shown) to simulate real arcing caused by loose cable connection and insulation breakdown, respectively. Resistors (not shown) were connected in parallel to the first load 216 and the second load 218 to meet the power requirement as per the IEC 62606 standard.

The four different load types (e.g., groups) and their corresponding number of arc and non-arc (e.g., normal) current samples and their corresponding labels are provided in Table I, above, and will not be repeated for the sake of brevity. The arcing currents of the different load types are labeled with even numbers (0, 2, 4, 6, and 8) and the normal load currents of the different load types are labeled with odd numbers (1, 3, 5, and 7) in Table I.

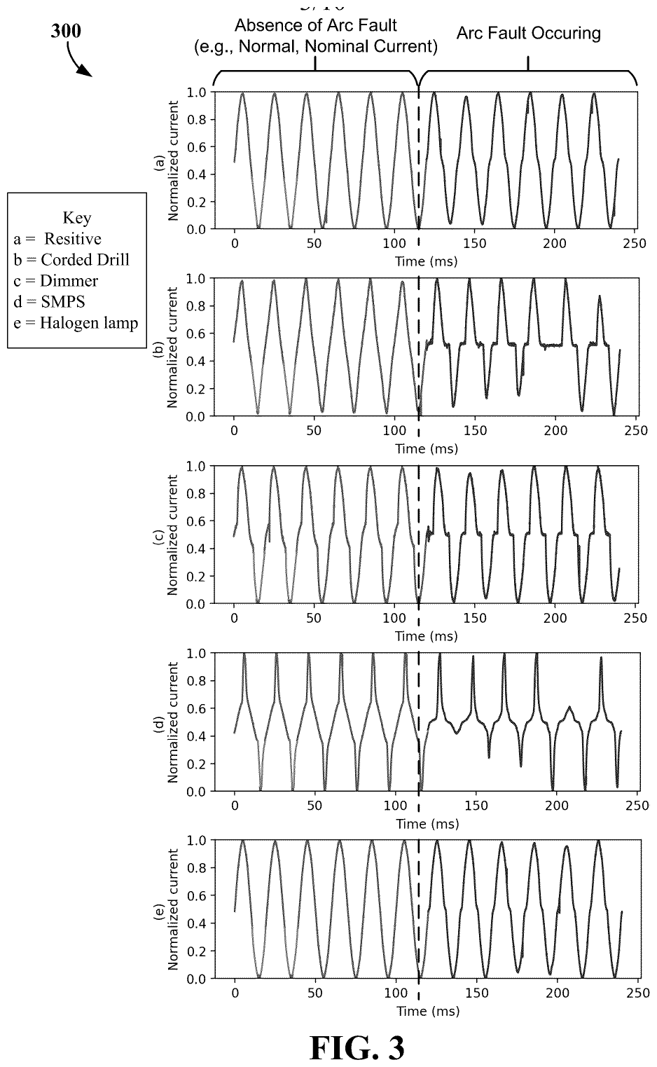

FIG. 3 depicts five graphs of normalized current versus time for five different load types according to some aspects of the disclosure. In each of the five graphs of FIG. 3, time is depicted on the horizontal axis in units of ms. Normalized current is depicted on the vertical axis with units of mA. Each of the five graphs depicts the normal current (e.g., current in the absence of an arc fault) on the left half of each graph and the arcing current (e.g., the current during an arc fault event) on the right half of each graph.

As depicted in FIG. 3, arcing load current is different from the normal load current. However, the normal load current appears differently depending on different load types. Some normal load currents are mostly sinusoidal, some have flat shoulders as well as catastrophe points. Arcing currents, on the other hand, show many visual phenomena including distorted waveform, decreasing the amplitude of the current, an increase in the high-frequency component (harmonics), and a reduction in the conduction angle. In some cases, the normal current of one load type (dimmer) mimics the arcing current of another load type (heater). The stagnation period is the duration of the “current zero” state or “length of the flat shoulder” in one cycle of the current wave. The length of the flat shoulder, which may be present in the normal load current, may increase when arcing occurs. Also, depending on the arcing intensities, the current wave shape may become distorted in different ways. Apart from this, in most cases, the high-frequency harmonics components may increase due to the presence of an arc in the load current.

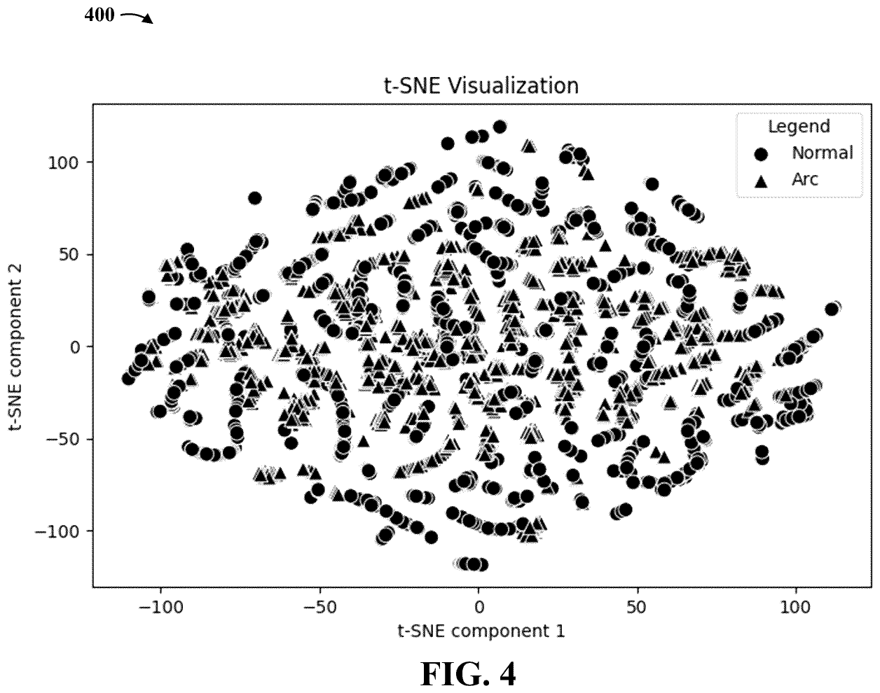

FIG. 4 is a T-Distributed Stochastic Neighbor Embedding (T-SNE) visualization 400 of normal current data (i.e., current without evidence of the occurrence of arc fault(s)) and arc fault current data in the frequency domain according to some aspects of the disclosure. To produce FIG. 4, the arc fault current time domain data and the normal current time domain data were converted into frequency domain data using a Fast Fourier Transform (FFT) method. The sampling frequency of this data is 40 kHz. The data with 10 kHz sampling rate is not considered in this case because 40 kHz data will preserve more high-frequency components in the current signal. The T-Distributed Stochastic Neighbor Embedding (T-SNE) method is a dimensionality reduction technique that is widely used for visualizing high-dimensional data in a low-dimensional space. It maps high-dimensional data points into a 2D, or 3D space, preserving the structure and relationships between the data points as much as possible, making it easier to visualize and understand complex data distributions. It can be seen that the arcing current samples (depicted as ▴s) and normal current samples (depicted as •s) of the different loads are scattered over the entire projection region. As recognizable from the data, it is difficult to achieve a simple decision boundary (threshold) to classify the arcing data from the normal current in the frequency domain.

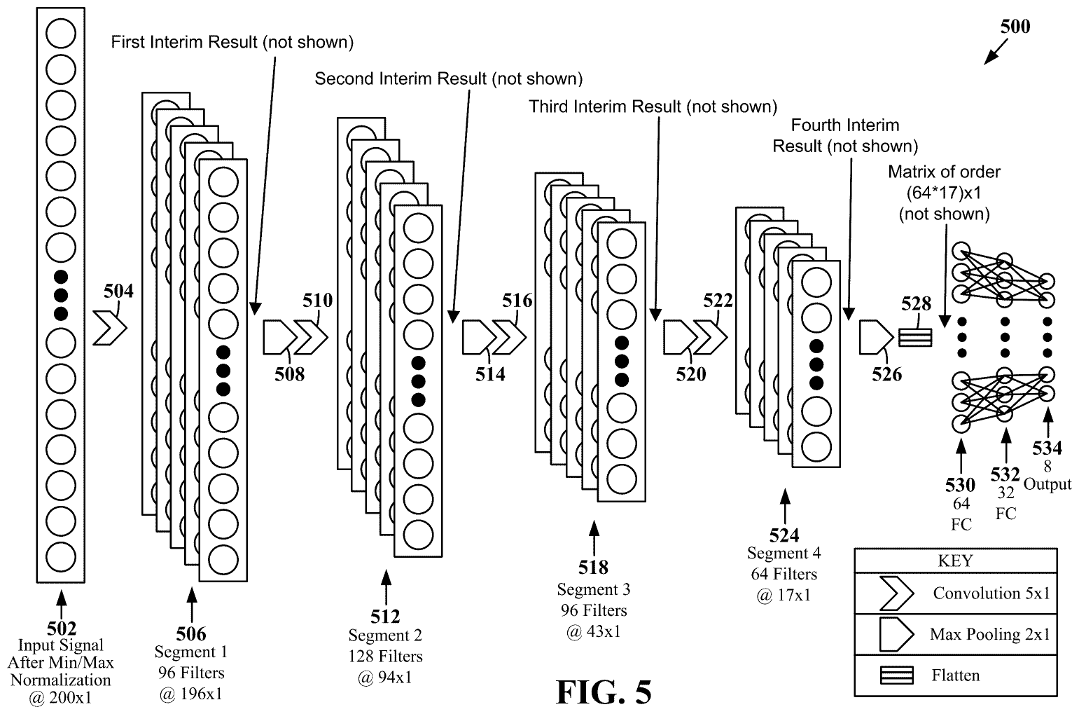

FIG. 5 is an exemplary convolutional neural network model 500 according to some aspects of the disclosure. A leftmost matrix 502 has an order of 200 rows×1 column (i.e., an order of 200×1). The leftmost matrix 502 may represent the input signal representative of the current (i(t)) (134, FIG. 1) passing through the first circuit (101, FIG. 1). In some aspects, the leftmost matrix 502 may represent the input signal after a normalization (e.g., a min-max normalization). In some aspects, the leftmost matrix 502 may represent the input signal after normalization and after preprocessing (e.g., time domain feature extraction, Fast Fourier Transform (FFT), etc.).

According to some aspects, the leftmost matrix 502 may be convolved 504 with a first segment 506 comprised of 96 filter matrixes each having an order of 196×1, to produce a first interim result (not shown).

The first interim result (not shown) may undergo max pooling 508 and then may be convolved 510 with a second segment 512 comprised of 128 filter matrixes each having an order of 94×1, to produce a second interim result (not shown). As known to persons having ordinary skill in the art, max pooling is technique used in convolutional neural networks to reduce the spatial dimensions of an input volume. Max pooling may be understood as a form of non-linear down-sampling that makes a given representation smaller and more manageable. To visualize an explanation of mx pooling, a person may imagine sliding a window (often called a filter or kernel) across a set of input data (e.g., a feature map). Instead of doing lengthy matrix multiplication, max pooling may be used to obtain the maximum value within that sliding window. The result of the max pooling may be a down-sampled (pooled) feature map that retains essential information while reducing the computational load.

The second interim result (not shown) may undergo max pooling 514 and then may be convolved 516 with a third segment 518 comprised of 96 filter matrixes each having an order of 43×1, to produce a third interim result (not shown).

The third interim result (not shown) may undergo max pooling 520 and then may be convolved 522 with a fourth segment 524 comprised of 64 filter matrixes each having an order of 17×1, to produce a fourth interim result (not shown).

The fourth interim result (not shown) may undergo max pooling 526 and then may be flattened 528 to produce a matrix of order (64*17)×1 (not shown).

The matrix of order (64*17)×1 (not shown) may be converted to a fully connected (FC) set of 64 neurons 530.

The FC set of 64 neurons 530 may be fully connected to an FC set of 32 neurons 532.

The FC set of 32 neurons 533 may be fully connected to an FC set of 8 neurons 534.

The FC set of 8 neurons 534 may be fully connected to a set of two neurons (not shown to avoid cluttering the drawing). From the set of two neurons, the convolutional neural network model 500 may, for example, drive one or more output nodes (e.g., represented as output node 131, FIG. 1) of the second circuit (128, FIG. 1) according to a detection by the convolutional neural network model 500 of an arc fault in the current (134, FIG. 1) passing through the first circuit (101, FIG. 1), where the one or more output nodes (e.g., represented as output node 131, FIG. 1) may be driven to a first value indicative of an absence of the detection of the arc fault in the current passing through the first circuit, or a second value indicative of the detection of the arc fault in the current passing through the first circuit.

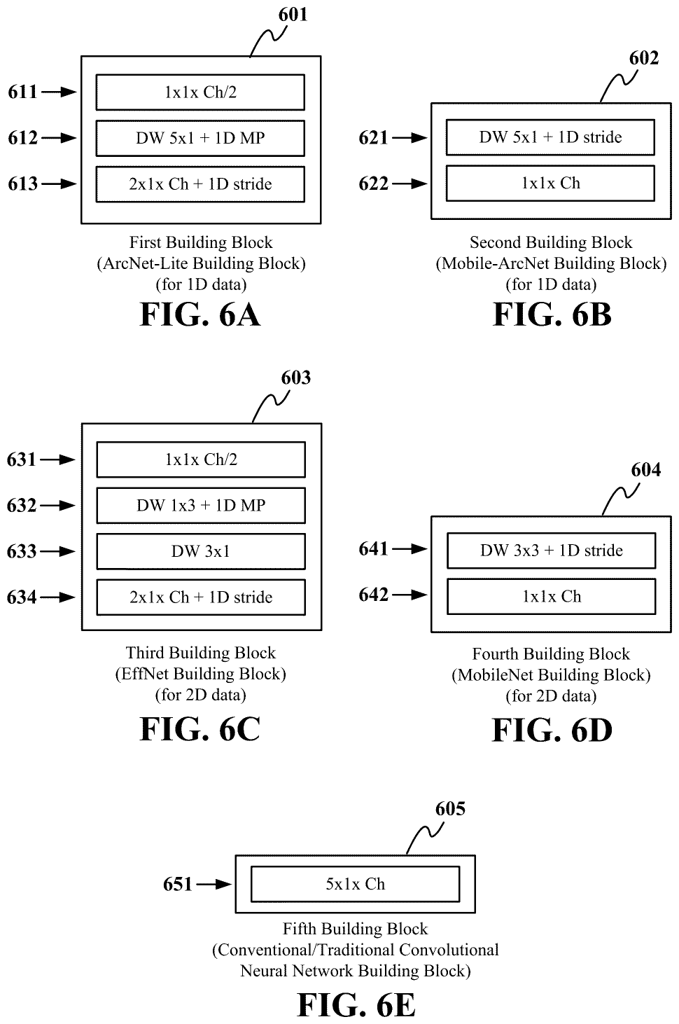

FIGS. 6A, 6B, 6C, 6D are illustrations describing four convolutional neural network building blocks according to some aspects of the disclosure. The terms depthwise convolution and pointwise convolution are used in the following illustrations. As known by persons having ordinary skill in the art, in a standard convolutional layer, computation happens in one step across both channels (depth) and spatial dimensions (width and height). However, depthwise separable convolution splits this computation into two steps; namely, depthwise convolution and pointwise convolution. In depthwise convolution, a single convolutional filter is applied per input channel. In other words, depthwise convolution performs a separate convolution for each channel independently. In pointwise convolution (sometimes referred to as 1×1 convolution), subsequent to a depthwise convolution, a 1×1 kernel (e.g., a filter that iterates through every single point) is used to create a linear combination of the output from the depthwise convolution. This step combines information across channels. The result is a more efficient and lightweight convolutional operation, which reduces the number of parameters while maintaining expressive power. However, pointwise convolutions may be used apart from depthwise convolutions. As just described, a pointwise convolution may use a 1×1 kernel. A pointwise convolution may operate on an entire input volume, iterating through each point (pixel). The depth of the 1×1 kernel matches the number of channels in the input image. Pointwise convolutions are often used in conjunction with depthwise convolutions to create depthwise-separable convolutions, which strike a balance between efficiency and performance; however, a pointwise convolution may be used on its own. In summary, a depthwise convolution focuses on spatial dimensions (channels separately). A pointwise convolution combines information across channels. Using a pointwise convolution following a depthwise convolution may produce a depthwise separable convolution.

As used herein, the term “ID convolution” may be a depthwise convolution, a pointwise convolution, or a regular ID convolution. In the examples below, a 1D convolution represents a regular 1D convolution layer with Ch filters having smaller (2×1) kernel size of the filter unless otherwise stated. In the examples herein, one-dimensional aspects have been exemplified in cases where the data may be ID, not 2D.

FIG. 6A depicts a first building block 601 (also referred to as an ArcNet-Lite building block), which may be useful with one-dimensional data, according to some aspects of the disclosure. The first building block 601 includes three sub-layers. A first sub-layer 611 of the first building block 601 represents a one-dimensional (1D) pointwise convolution of the input signal data (not shown) with one-half of the available channels or filter matrixes (Ch/2), where each channel or filter matrix is a 1×1 matrix. A second sub-layer 612 represents a 1D depthwise convolution applied to the result (not shown) of first sub-layer 611 with one-half of the available channels or filter matrixes, where each channel or filter matrix is a 5×1 matrix, followed by a max pooling layer (of pooling size 2×1). A third sub-layer 613 represents a ID convolution applied to the result (not shown) of the second sub-layer 612 with all the available channels or filter matrixes (Ch), where each channel or filter matrix is a 2×1 matrix, with a 1D stride of 2.

FIG. 6B depicts a second building block 602 (also referred to as a Mobile-ArcNet building block), which may be useful with one-dimensional data, according to some aspects of the disclosure. The second building block 602 includes two sub-layers. A first sub-layer 621 of the second building block 602 represents a one-dimensional (1D) depthwise convolution of the input signal data (not shown) with all available channels or filter matrixes (Ch), where each channel or filter matrix is a 5×1 matrix. A second sub-layer 622 of the second building block 602 represents a 1D depthwise convolution of the result (not shown) of the first sub-layer 621 with all the available channels or filter matrixes (Ch), where each channel or filter matrix is a 1×1 matrix.

FIG. 6C depicts a third building block 603 (a.k.a. an EffNet building block), according to some aspect of the disclosure. The third building block 603 may be useful with two-dimensional (2D) data. The third building block 603 includes four sub-layers. A first sub-layer 631 of the third building block 603 represents a one-dimensional (1D) pointwise convolution of the input signal data (not shown) with one-half of the available channels or filter matrixes (Ch/2), where each channel or filter matrix is a 1×1 matrix. A second sub-layer 632 of the third building block 603 represents a ID depthwise convolution of the result (not shown) of the first sub-layer 631 with a 1×3 matrix, plus a 1 max pooling. A third sub-layer 633 of the third building block 603 represents a ID depthwise convolution of the result (not shown) of the second sub-layer 632 with a 3×1 matrix. A fourth sub-layer 634 of the third building block 603 represents a 1D pointwise convolution of the result (not shown) of the third sub-layer 633 with all the available channels or filter matrixes (Ch), where each channel or filter matrix is a 2×1 matrix, with a 1D stride.

FIG. 6D depicts a fourth building block 604 (a.k.a. a MobileNet building block), according to some aspects of the disclosure. The fourth building block 604 may be useful with two-dimensional data. The fourth building block 604 includes two sub-layers. A first sub-layer 641 of the fourth building block 604 represents a one-dimensional (1D) depthwise convolution of the input signal data (not shown) with a 3×3 matrix, plus a 1D stride. A second sub-layer 642 of the fourth building block 604 represents a one-dimensional (1D) pointwise convolution of the result (not shown) of the first sub-layer 641 with all channels or filter matrixes (Ch), where each channel or filter matrix is a 1×1 matrix.

FIG. 6E depicts a fifth building block 605. The fifth building block 605 may be referred to as a traditional or conventional convolutional neural network (CNN) building block. The fifth building block 605 includes one sub-layer. A first sub-layer 651 of the fifth building block 605 represents a one-dimensional (1D) pointwise convolution of the input signal data (not shown) with all channels or filter matrixes (Ch).

The first building block 601 (a.k.a. ArcNet-Lite building block) exhibits a reduction in the required computational complexity of a convolutional neural network model in comparison to that required for the third building block 603, the second building block 602, or the fifth building block 605. The first building block 601 may have the lowest computational complexity compared to the second building block 602, the third building block 603, the fourth building block 604, and the traditional convolutional neural network (CNN) building block (the fifth building block 605). As noted in FIGS. 6A-6D, the first building block 601 and the second building block 602 are described for use with 1D data, and the third building block 603 and the fourth building block 604 are described for use with 2D data. The architecture of the first building block 601 may be constructed using a pointwise convolution at the first sub-layer 611 of the first building block 601 followed by a depthwise convolution and a max pooling (MP) at the second sub-layer 612 of the first building block 601. This network architecture reduces the computational complexity at the beginning of computations (in comparison to the computational complexity of the second building block 602, sometimes referred to as the Mobile-ArcNet building block).

The reduced computational complexity is achieved throughout the convolutional neural network architecture because the remainder of the architecture utilizes copies of the first building block 601. This strategy helps to maintain a lightweight design while ensuring consistent performance across the network. Additionally, the number of trainable parameters is significantly reduced compared to a conventional convolutional neural network structure, such as in the case of the fifth building block 605.

The pointwise convolution layer (i.e., the first sub-layer 611) may be designed with half of the filters as used in a conventional convolutional neural network (CNN) model (such as the fifth building block 605 of FIG. 6E). The depthwise separable layer of size 5×1 (i.e., the second sub-layer 612) uses the same number of filters (i.e., half of the filters) as was used in the first sub-layer 611. The second sub-layer 612 is followed, in the same second sub-layer 612, by a 1D max pooling of pooling size 2×1. At the third sub-layer 613 of the first building block 601, a convolutional layer of size 2×1 with all channels (Ch) (i.e., all filters) with a 1D stride of 2 may be employed on the third sub-layer 613.

The convolutional neural network architecture that utilizes a plurality of the first building block 601, and which may be configured in one or more processors, also avoids a stringent bottleneck structure found in the fourth building block 604 (a.k.a. the MobileNet building block); avoiding this stringent bottleneck contributes to the creation of a lightweight convolutional neural network model, such as a model that may employ a series combination of a plurality of the first building block 601. As used herein, the word lightweight refers to a complexity of the convolutional neural network configuration. For example, and without any intention of limiting the scope of the disclosure, a lightweight convolutional neural network model may be configured on a type of processor that has reduced computational capability (e.g., a Raspberry Pi, or STM32) in comparison, for example, to a processor employed in a gaming computer (e.g., an Intel Core i5).

The first building block 601 may be less complex than the third building block 603, for example. Indeed, in a sense it may have the lowest complexity compared to all other building blocks in FIGS. 6B-6E. At least one reason for the reduced complexity may be that the first building block 601 is designed for 1D time series data, while the third building block 603 is designed for 2D time series data. Due at least to this difference, the third sub-layer 633 of the third building block 603 (a.k.a. the EffNet building block) is not required in the first building block 601 convolutional neural network architecture. Also, the first building block 601 may be less complex than the second building block 602 or the fifth building block 605 due to the use of pointwise and depthwise convolution layers in the first building block 601. Another reason for the reduced complexity may be that in the network design a knowledge distillation-based model compression technique was used.

Experimental data (not shown) exhibits poorer performance with a 3×1 kernel size in comparison to a 5×1 kernel size. Also, a larger kernel size increases the computational complexity, therefore, the kernel size of 5×1, as used in the first building block 601, may be a preferred size (at least in comparison to the size of 3×1).

FIG. 6B depicts a second building block 602, which is another lightweight deep neural network model. Instead of using pointwise convolution at the first sub-layer 621 of the second building block 602, the second building block 602 uses depthwise convolution at the first sub-layer 621. Moreover, it does not use max pooling at any sub-layer. This is why the complexity carries forward to the rest of the network model when used in network design. The second building block 602 has a 3×3 depthwise separable convolution layer followed by a stride of 2 (i.e., the first sub-layer 621). In contrast to the fourth building block 604, which is designed for 2D data with a 2D convolution layer, the second building block 602 is designed for 1D data with a ID convolution layer (i.e., first sub-layer 621).

The objective was to check if the second building block 602 has a lower computational burden than the first building block 601. In contrast to the first sub-layer 621 of the second building block 602, the second building block 602 is configured for 1D data, and hence it starts with a 5×1 depthwise separable convolution instead of 3×3 depthwise separable convolution. The depthwise separable convolution layer (i.e., the second sub-layer 622) is followed by a pointwise convolution with the full number of filters, each having a filter size of 5×1. The basic building block of the second building block 602 (a.k.a. the Mobile-ArcNet) is depicted in FIG. 6B.

Possible building blocks, such as the first building block 601 (a.k.a. the ArcNet-Lite building block) and the second building block 602 (a.k.a. the Mobile-ArcNet) of an efficient convolutional neural network model according to some aspects of the disclosure are described herein. There may be several strategies for making an efficient deep convolutional neural network. One strategy may involve using a convolutional neural network architectures that incorporate the first building block 601 and/or the second building block 602, which are more efficient than the third building block 603 (a.k.a. the EffNet building block), the fourth building block 604 (a.k.a. the MobileNet building block), and fifth building block 605 (a.k.a. the conventional CNN layer). Another strategy may involve using a network compression method such as knowledge distillation.

Certain features of the convolutional neural network models configured with a plurality of the first building block 601 or a plurality of the second building block 602 described herein provide evidence of the efficiency of their architectures. Pros and cons of the third building block 603, the fourth building block, and the fifth building block in view a design of a convolutional neural network model utilizing a plurality of the first building block 601 may be offered herein. According to some aspects, the entirety of convolutional neural network model described herein is constructed using copies of (a plurality of) the first building block 601 as described and shown in FIG. 6A herein.

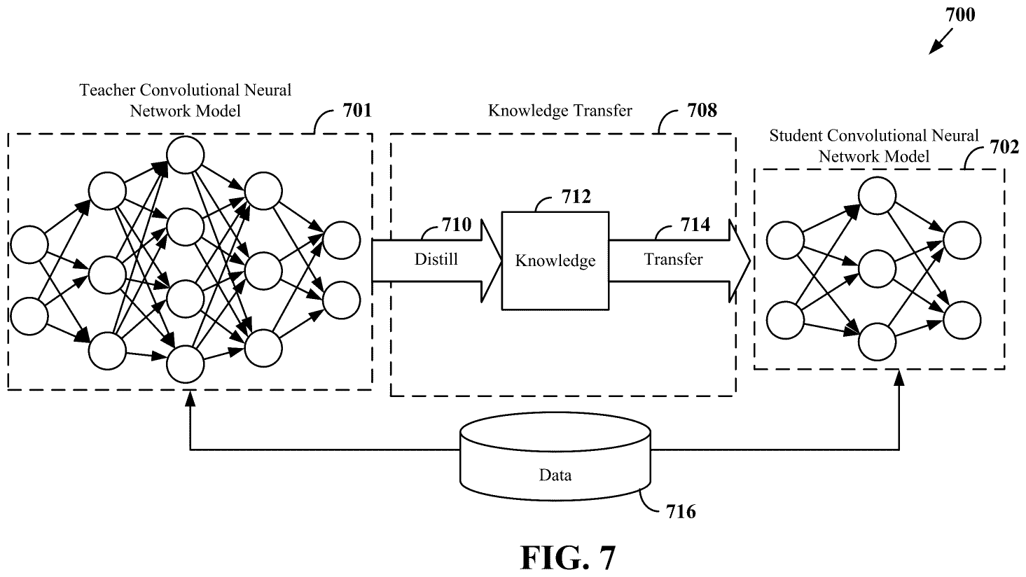

FIG. 7 is a schematic representation of a framework of a teacher-student knowledge distillation model 700 according to some aspects of the disclosure. According to some aspects, a teacher convolutional neural network model 801 (FIG. 8A) and a student convolutional neural network model 802 (FIG. 8B) may be developed. The student convolutional neural network model 802 may benefit from knowledge obtained by the teacher convolutional neural network model 801 and transferred to the student convolutional neural network model 802. According to some examples, the teacher convolutional neural network model 801 is trained prior to the knowledge transfer (in other words, the student convolutional neural network model 802 may receive knowledge from a pretrained teacher convolutional neural network model 801.

A teacher-student knowledge distillation (KD) technique may be employed to transfer knowledge obtained by a teacher convolutional neural network model 701 (also 801 of FIG. 8) to a student convolutional neural network model 702 (also 802 of FIG. 8). The teacher-student knowledge distillation technique is a model compression method that may be utilized in connection with configuring deep neural networks, such as those described herein. The teacher-student knowledge distillation technique described herein may have a benefit of making a proposed convolutional neural network model lightweight. The lightweight aspect may be realized, for example, because quantities of calculations required of a given convolutional neural network may be passed from the student convolutional neural network model 702 to the teacher convolutional neural network model 701.

The one or more processors and processing system configuring the teacher convolutional neural network model 701 may have greater computational capability and grater storage capability in comparison to the one or more processors and processing system configuring the student convolutional neural network model 702. By relieving the student of some computational requirements, the demands made on the student are reduced. This reduction may contribute toward making the proposed student convolutional neural network model 702 lightweight.

In the knowledge distillation technique, the teacher convolutional neural network model 701 (which is relatively large compared to the student convolutional neural network model 702) supervises the student convolutional neural network model 702 (which is relatively small compared to the teacher convolutional neural network model 701). The student convolutional neural network model 702 mimics the teacher convolutional neural network model 701 to achieve comparable or even superior performance than the teacher convolutional neural network model 701.

There are three main components in the KD technique, namely knowledge 706, teacher-student architecture (i.e., the teacher convolutional neural network model 701 and the student convolutional neural network model 702), and knowledge transfer 708, which may include the distilled 710 knowledge 712 obtained by the teacher convolutional neural network model 701, and the transfer 714 of the knowledge 712 from a knowledge database (represented by the knowledge 712 block) to the student convolutional neural network model 702.

The respective teacher and student convolutional neural network models may use response-based knowledge. The overall system includes a strong teacher model and a comparatively weaker student model. The teacher model is stronger so that it can gain as much information as possible from the data 716 available to both the teacher and student models. The knowledge 712 is then distilled 710 from the teacher convolutional neural network model 701 to transfer 714 to the student convolutional neural network model 702. The student convolutional neural network model 702 has a simpler architecture compared to the teacher convolutional neural network model 701. However, the main body structure (number of convolutional neural networks and FC layers) of the student convolutional neural network model 702 is similar to that of the teacher convolutional neural network model 701.

The student convolutional neural network model 702 may have a reduced number of filters (e.g., channels) and neurons in layers corresponding to those of the teacher convolutional neural network model 701 as described and shown in connection with FIG. 8A and FIG. 8B, below.

FIG. 8A is a schematic representation of a teacher convolutional neural network model 801 according to some aspects of the disclosure. FIG. 8B is a schematic representation of a student convolutional neural network model 802 according to some aspects of the disclosure. The convolutional neural network architecture of each model may be implemented in an apparatus that includes one or more memories and one or more processors coupled to the one or more memories. In the apparatus, the one or more processors may be configured to (individually or collectively, based at least in part on information stored in the one or more memories) obtain an input signal (e.g., input signal 803 in connection with the teacher convolutional neural network model 801, input signal 807 in connection with the student convolutional neural network model 802) representative of a current passing through a first circuit (e.g., first circuit 101 as shown and described in connection with FIG. 1). The one or more processors may be configured to apply the input signal to one or more input nodes (e.g., input node 129 as shown and described in connection with FIG. 1) of a second circuit (e.g., second circuit 128 as shown and described in connection with FIG. 1), different from the first circuit according to a convolutional neural network model.

According to some aspects, the one or more processors may be configured to realize the convolutional neural network as a plurality of building blocks (e.g., three copies of one class of building block, such as but not limited to the first building block 601 as shown and described in connection with FIG. 6A). In one example the plurality of building blocks are duplicates of one another. According to some aspects, where the convolutional neural network is configured as a plurality of building blocks, each building block may include a plurality of sub-layers. Using the first building block 601 as an example, each building block may include a one-dimensional pointwise convolution with one-half of all filters at a first sub-layer (e.g., the first sub-layer 611 of the first building block 601 as shown and described in connection with FIG. 6A), where each of the one-half of all filters at the first sub-layer is a 1×1 matrix, followed by a one-dimensional depthwise convolution with one-half of all filters at a second sub-layer (e.g., the second sub-layer 612 of the first building block 601 as shown and described in connection with FIG. 6A) followed by a max pooling at the second sub-layer, where each of the one-half of all filters at the second sub-layer is 5×1 matrix, and followed by a one-dimensional pointwise convolution with all filters at a third sub-layer (e.g., the third sub-layer 613 of the first building block 601 as shown and described in connection with FIG. 6A) along with a one-dimensional stride of two at the third sub-layer, wherein each of the all filters at the third sub-layer is a 2×1 matrix. For added explanation, the reference to the one-dimensional (1D) stride above is intended to indicate that the 1D stride of 2 is used alongside the third sub-layer; in other words, it is a parameter associated with the third sub-layer 613 of the first building block 601 as shown and described in connection with FIG. 6A.

For example, consider the teacher convolutional neural network model 801 of FIG. 8A. At the far left, a 200×1 matrix representing the input signal 803 is depicted. A first instance of the first building block 810a, precedes a second instance of the first building block 810b, which precedes a third instance of the first building block 810c. The first instance of the first building block 810a includes 256 channels. The second instance of the first building block 810b includes 512 channels. The third instance of the first building block 810c includes 512 channels. Each instance of the first building block may be similar to the first building block 601 as shown and described in connection with FIG. 6. The preceding numbers of channels are provided for explanatory, exemplary, and non-limiting purposes.

The input signal 803 is applied to the first instance of the first building block 810a. At the start, the 200×1 matrix representing the input signal 803 is exposed to a one-dimensional pointwise convolution 812 with one-half of all filters at a first sub-layer (e.g., 256/2 filters), wherein each of the one-half of all filters at the first sub-layer is a 1×1 matrix. The result is a first 200×128 matrix 850.

The first 200×128 matrix 850 is exposed to a one-dimensional depthwise convolution 814 with one-half of the filters at a second sub-layer followed by a max pooling 816 at the second sub-layer, where each filter of the one-half of all filters of the second sub-layer is a 5×1 matrix. The result is a second 200×128 matrix (not shown). The second 200×128 matrix (not shown) would be positioned between the max pooling 816 and the 1D convolution with stride of 2 818).

The second 200×128 matrix (not shown) is exposed to a one-dimensional pointwise convolution 818 with all filters (i.e., 256 filters) at a third sub-layer followed by a one-dimensional stride at the third sub-layer, wherein each of the all filters at the third sub-layer is a 2×1 matrix. The result is a first 49×256 matrix 851.

Thereafter, the first 49×256 matrix 851 is applied to the second instance of the first building block 810b. At the start, the 49×256 matrix 851 is exposed to a one-dimensional pointwise convolution 812 with one-half of all filters at a first sub-layer (e.g., 512/2 filters), wherein each of the one-half of all filters at the first sub-layer is a 1×1 matrix. The result is a second 49×256 matrix 852.

The second 49×256 matrix 852 is exposed to a one-dimensional depthwise convolution 814 with one-half of the filters at a second sub-layer followed by a max pooling 816 at the second sub-layer, where each filter of the one-half of all filters at the second sub-layer is a 5×1 matrix. The result is a third 49×256 matrix (not shown). The third 49×256 matrix (not shown) would be positioned between the max pooling 816 and the 1D convolution with stride of 2 818).

The third 49×256 matrix (not shown) is exposed to a one-dimensional pointwise convolution 818 with all filters (i.e., 512 filters) at a third sub-layer followed by a one-dimensional stride at the third sub-layer, wherein each of the all filters at the third sub-layer is a 2×1 matrix. The result is a first 11×512 matrix 853.

Thereafter, the first 11×512 matrix 853 is applied to the third instance of the first building block 810c. At the start, the first 11×512 matrix 853 is exposed to a one-dimensional pointwise convolution 812 with one-half of all filters at a first sub-layer (e.g., 512/2 filters), wherein each of the one-half of all filters at the first sub-layer is a 1×1 matrix. The result is a first 11×256 matrix 854.

The first 11×256 matrix 854 is exposed to a one-dimensional depthwise convolution 814 with one-half of the filters at a second sub-layer followed by a max pooling 816 at the second sub-layer, where each filter of the one-half of all filters at the second sub-layer is a 5×1 matrix. The result is a second 11×256 matrix (not shown). The second 11×256 matrix (not shown) would be positioned between the max pooling 816 and the 1D convolution with stride of 2 818).

The second 11×256 matrix (not shown) is exposed to a one-dimensional pointwise convolution 818 with all filters (i.e., 512 filters) at a third sub-layer followed by a one-dimensional stride at the third sub-layer, wherein each of the all filters at the third sub-layer is a 2×1 matrix. The result is a 1×512 matrix 855.

Thereafter, the 1×512 matrix 855 is flattened 805, resulting in a 128 neuron fully connected (128 FC) layer 830. The 128 FC layer 830 reduces to a 64 FC layer 832. The 64 FC layer 832 reduces to an 8 FC layer 834. The 8 FC layer 834 reduces to a 2 FC output layer 836. The two neurons at the 2 FC output layer 836 may represent a first value indicative of an absence of the detection of the arc fault in the current passing through the first circuit, and a second value indicative of the detection of the arc fault in the current passing through the first circuit, respectively.

The one or more processors may be further configured to drive one or more output nodes (e.g., output node 131 as shown and described in connection with FIG. 1) of the second circuit (e.g., the second circuit 128 as shown and described in connection with FIG. 1) according to a detection by the convolutional neural network model (e.g., the teacher convolutional neural network model 801 as shown and described in connection with FIG. 8A) of an arc fault in the current (e.g., the current 134 as shown and described in connection with FIG. 1) passing through the first circuit (e.g., the first circuit 101 as shown and described in connection with FIG. 1), the one or more output nodes driven to either a first value indicative of an absence of the detection of the arc fault in the current passing through the first circuit (e.g., as present at a first of the two neurons at the 2 FC output layer 836 of the teacher convolutional neural network model 801 of FIG. 8A), or a second value indicative of the detection of the arc fault in the current passing through the first circuit (e.g., as present at a second of the two neurons at the 2 FC output layer 836 of the teacher convolutional neural network model 801 of FIG. 8A).

However, the teacher convolutional neural network model 801 is more computationally complex than the student convolutional neural network model 802 and may require more storage (e.g., memory) than the student convolutional neural network model 802. Accordingly, using the knowledge distillation technique as shown and described in connection with FIG. 7, knowledge gained by the teacher convolutional neural network model 801 of FIG. 8 (similar to 701, FIG. 7) may be distilled (e.g., 710, FIG. 7) into a knowledge reservoir or database (e.g., 712, FIG. 7) and transferred (e.g., 714, FIG. 7) to the student convolutional neural network model 802 (similar to 702, FIG. 7). Thus, the student convolutional neural network model 802 may be trained by the pretrained teacher convolutional neural network model 801 according to some aspects of the disclosure.

For example, consider the student convolutional neural network model 802 of FIG. 8B (where, according to some aspects, the student convolutional neural network model 802 of FIG. 8B is trained by the teacher convolutional neural network model 801 of FIG. 8A). At the far left, a 200×1 matrix representing the input signal 807 is depicted. A first instance of the first building block 820a, precedes a second instance of the first building block 820b, which precedes a third instance of the first building block 820c. The first instance of the first building block 820a includes 16 channels (compared to the 256 channels associated with the first instance of the first building block 810a associated with the teacher convolutional neural network model 801). The second instance of the first building block 810b includes 32 channels (compared to the 512 channels associated with the second instance of the first building block 810b associated with the teacher convolutional neural network model 801). The third instance of the first building block 810c includes 32 channels (compared to the 512 channels associated with the third instance of the first building block 810c associated with the teacher convolutional neural network model 801). Each instance of the first building block may be similar to the first building block 601 as shown and described in connection with FIG. 6. The preceding numbers of channels are provided for explanatory, exemplary, and non-limiting purposes.

The input signal 807 is applied to the first instance of the first building block 820a. At the start, the 200×1 matrix representing the input signal 807 is exposed to a one-dimensional pointwise convolution 812 with one-half of all filters at a first sub-layer (e.g., 16/2 filters), wherein each of the one-half of all filters at the first sub-layer is a 1×1 matrix. The result is a first 200×8 matrix 860.

The first 200×8 matrix 860 is exposed to a one-dimensional depthwise convolution 814 with one-half of the filters at a second sub-layer followed by a max pooling 816 at the second sub-layer, where each filter of the one-half of all filters of the second sub-layer is a 5×1 matrix. The result is a second 200×8 matrix (not shown). The second 200×8 matrix (not shown) would be positioned between the max pooling 826 and the ID convolution with stride of 2 828).

The second 200×8 matrix (not shown) is exposed to a one-dimensional pointwise convolution 828 with all filters (i.e., 16 filters) at a third sub-layer followed by a one-dimensional stride at the third sub-layer, wherein each of the all filters at the third sub-layer is a 2×1 matrix. The result is a first 49×16 matrix 861.

Thereafter, the first 49×16 matrix 861 is applied to the second instance of the first building block 820b. At the start, the 49×16 matrix 861 is exposed to a one-dimensional pointwise convolution 822 with one-half of all filters at a first sub-layer (e.g., 32/2 filters), wherein each of the one-half of all filters at the first sub-layer is a 1×1 matrix. The result is a second 49×16 matrix 862.

The second 49×16 matrix 862 is exposed to a one-dimensional depthwise convolution 824 with one-half of the filters at a second sub-layer followed by a max pooling 826 at the second sub-layer, where each filter of the one-half of all filters at the second sub-layer is a 5×1 matrix. The result is a third 49×16 matrix (not shown). The third 49×16 matrix (not shown) would be positioned between the max pooling 826 and the 1D convolution with stride of 2 828).

The third 49×16 matrix (not shown) is exposed to a one-dimensional pointwise convolution 828 with all filters (i.e., 32 filters) at a third sub-layer followed by a one-dimensional stride at the third sub-layer, wherein each of the all filters at the third sub-layer is a 2×1 matrix. The result is a first 11×32 matrix 863.

Thereafter, the first 11×32 matrix 863 is applied to the third instance of the first building block 820c. At the start, the first 11×32 matrix 863 is exposed to a one-dimensional pointwise convolution 822 with one-half of all filters at a first sub-layer (e.g., 32/2 filters), wherein each of the one-half of all filters at the first sub-layer is a 1×1 matrix. The result is a first 11×16 matrix 864.

The first 11×16 matrix 864 is exposed to a one-dimensional depthwise convolution 824 with one-half of the filters at a second sub-layer followed by a max pooling 826 at the second sub-layer, where each filter of the one-half of all filters at the second sub-layer is a 5×1 matrix. The result is a second 11×16 matrix (not shown). The second 11×16 matrix (not shown) would be positioned between the max pooling 826 and the ID convolution with stride of 2 828).

The second 11×16 matrix (not shown) is exposed to a one-dimensional pointwise convolution 828 with all filters (i.e., 32 filters) at a third sub-layer followed by a one-dimensional stride at the third sub-layer, wherein each of the all filters at the third sub-layer is a 2×1 matrix. The result is a 1×32 matrix 865.

Thereafter, the 1×32 matrix 865 is flattened 809, resulting in a 64 neuron fully connected (64 FC) layer 840. The 64 FC layer 840 reduces to a 32 FC layer 842. The 32 FC layer 842 reduces to an 8 FC layer 844. The 8 FC layer 844 reduces to a 2 FC output layer 846. The two neurons at the 2 FC output layer 846 may represent a first value indicative of an absence of the detection of the arc fault in the current passing through the first circuit, and a second value indicative of the detection of the arc fault in the current passing through the first circuit, respectively.

The one or more processors may be further configured to drive one or more output nodes (e.g., output node 131 as shown and described in connection with FIG. 1) of the second circuit (e.g., the second circuit 128 as shown and described in connection with FIG. 1) according to a detection by the convolutional neural network model (e.g., the student convolutional neural network model 802 as shown and described in connection with FIG. 8B) of an arc fault in the current (e.g., the current 134 as shown and described in connection with FIG. 1) passing through the first circuit (e.g., the first circuit 101 as shown and described in connection with FIG. 1), the one or more output nodes driven to either a first value indicative of an absence of the detection of the arc fault in the current passing through the first circuit (e.g., as present at a first of the two neurons at the 2 FC output layer 846 of the student convolutional neural network model 802 of FIG. 8B), or a second value indicative of the detection of the arc fault in the current passing through the first circuit (e.g., as present at a second of the two neurons at the 2 FC output layer 846 of the student convolutional neural network model 802 of FIG. 8B).

According to some aspects, the convolutional neural network model proposed herein (e.g., the student convolutional neural network model, the ArcNet-Lite model) may include a plurality of consecutive (e.g., cascaded, series-coupled) building blocks, such as the first building block 601 as shown and described in connection with FIG. 6A and as illustrated in the cascaded, series-coupled configuration in connection with FIG. 8B (for a student model) or FIG. 8A (for a teacher model).

The convolutional neural network model proposed herein may utilize a teacher-student knowledge distillation (KD) technique, which is a model compression method of deep neural networks that may server to make the convolutional neural network model proposed herein lightweight. In the knowledge distillation technique, there is a large teacher network that supervises a small student network that mimics the teacher network to achieve comparable or even superior performance. The teacher model is stronger so that it can gain as much information as possible from the data. The knowledge is then distilled and transferred to the student model, which has a simpler architecture. However, the main body structure (number of CNN and FC layers) of the student model is similar to that of the teacher model. The student model has a reduced number of filters (e.g., channels) and neurons than the corresponding layers of the teacher model.

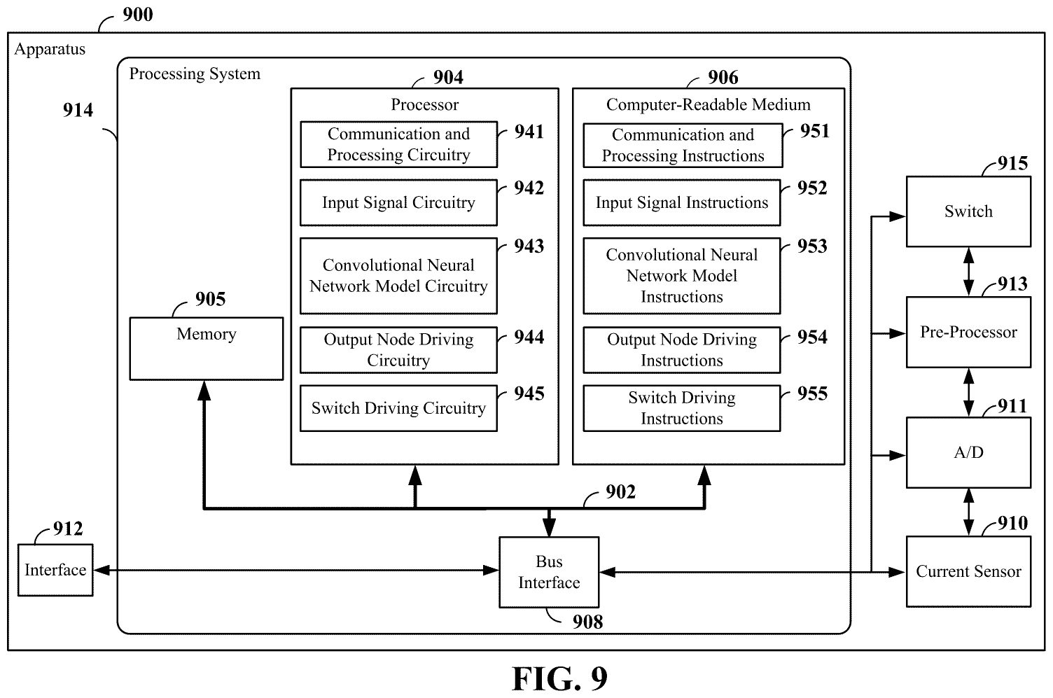

FIG. 9 is a block diagram illustrating an example of a hardware implementation of an apparatus 900, employing one or more processing systems (generally represented by processing system 914) according to some aspects of the disclosure. The apparatus 900 may be similar to, for example, any of the apparatus, devices, objects, or portions thereof depicted in FIGS. 1, 2, 6, 7, 8A and/or 8B.

In accordance with various aspects of the disclosure, an element, any portion of an element, or any combination of elements may be implemented with a processing system 914 that includes one or more processors, generally represented by processor 904, and one or more memories, generally represented by the memory 905 and additionally or alternatively generally represented by the computer-readable medium 906. Examples of processor 904 include microprocessors, microcontrollers, microcontroller units (MCUs), digital signal processors (DSPs), field programmable gate arrays (FPGAs), programmable logic devices (PLDs), state machines, gated logic, discrete hardware circuits, and other suitable hardware configured to perform the various functionality described throughout this disclosure. In various examples, the apparatus 900 may be configured to perform any one or more of the functions described herein. That is, the one or more processors (generally represented by processor 904), as utilized in the apparatus 900, may be configured to, individually or collectively, based at least in part on information stored in the one or more memories (generally represented by the memory 905 and additionally or alternatively generally represented by the computer-readable medium 906), implement (e.g., perform) any one or more of the methods or processes described and illustrated, for example, in FIGS. 1, 2, 3, 4, 5, 6, 7, 8A, and/or 8B.

In this example, the processing system 914 may be implemented with a bus architecture, represented generally by the bus 902. The bus 902 may include any number of interconnecting buses and bridges depending on the specific application of the processing system 914 and the overall design constraints. The bus 902 communicatively couples together various circuits, including one or more processors (generally represented by the processor 904), one or more memories (generally represented by the memory 905), and one or more computer-readable media (generally represented by the computer-readable medium 906). The bus 902 may also link various other circuits such as timing sources, peripherals, voltage regulators, and power management circuits, which are well known to persons having ordinary skill in the art and, therefore, will not be described any further.

A bus interface 908 may provide an interface between the bus 902 and, for example and if needed, one or more current sensors (generally represented by the current sensor 910), one or more analog-to-digital converters (generally represented by the analog-to-digital converter 911), one or more preprocessing devices/circuits/functions (generally represented by the preprocessing device/circuit/function 913), and/or one or more switches (generally represented by switch 915). The bus interface 908 may provide an interface between the bus 902 and a user interface 912 (e.g., keypad, display, touch screen, speaker, microphone, control features, vibration circuit/device, etc.). Of course, such a user interface 912 is optional and may be omitted in some examples.

According to some aspects, the one or more current sensors (e.g., 122, FIG. 1) coupled to the one or more processors, may be configured to derive a respective voltage waveform representative of the current (133, FIG. 1) flowing through the first circuit (101, FIG. 1) in a time domain. According to some aspects, the one or more analog-to-digital converter circuits (e.g., A/D converter 124, FIG. 1) may be coupled to the one or more current sensors (e.g., 122, FIG. 1) and the one or more processors (represented by processor 904) may be configured to sample the respective voltage waveform at a predetermined sampling rate to produce the input signal.

One or more processors, represented individually and collectively by processor 904, may be responsible for managing the bus 902 and general processing, including the execution of software stored (e.g., residing) on the memory 905 and/or the computer-readable medium 906. Software shall be construed broadly to mean instructions, instruction sets, code, code segments, program code, programs, subprograms, software modules, applications, software applications, software packages, routines, subroutines, objects, executables, threads of execution, procedures, functions, etc., whether referred to as software, firmware, middleware, microcode, hardware description language, or otherwise. The software, when executed by the one or more processors (generally represented by the processor 904), causes the one or more processing systems (generally represented by the processing system 914) to perform the various processes and functions described herein for any particular apparatus.

The computer-readable medium 906 may be a non-transitory computer-readable medium and may be referred to as a computer-readable storage medium or a non-transitory computer-readable medium. The non-transitory computer-readable medium may store computer-executable code (e.g., processor-executable code). The computer executable code may include code for causing a computer (e.g., a processor) to implement one or more of the functions described herein. A non-transitory computer-readable medium includes, by way of example, a magnetic storage device (e.g., hard disk, floppy disk, magnetic strip), an optical disk (e.g., a compact disc (CD) or a digital versatile disc (DVD)), a smart card, a flash memory device (e.g., a card, a stick, or a key drive), a random access memory (RAM), a read only memory (ROM), a programmable ROM (PROM), an erasable PROM (EPROM), an electrically erasable PROM (EEPROM), a register, a removable disk, and any other suitable medium for storing software and/or instructions that may be accessed and read by a computer. The computer-readable medium 906 may reside in the processing system 914, external to the processing system 914, or distributed across multiple entities, including the processing system 914. The computer-readable medium 906 may be embodied in a computer program product or article of manufacture. For example, a computer program product or article of manufacture may include a computer-readable medium in packaging materials. In some examples, the computer-readable medium 906 may be part of the memory 905. Persons having ordinary skill in the art will recognize how best to implement the described functionality presented throughout this disclosure depending on the particular application and the overall design constraints imposed on the overall system. The computer-readable medium 906 and/or the memory 905 may also be used for storing data that is manipulated by the processor 904 when executing software.

In some aspects of the disclosure, the one or more processors (generally represented by the processor 904) may include communication and processing circuitry 941 configured for various functions, including, for example, communication with other apparatus and performing processing processes. In some examples, the communication and processing circuitry 941 may include one or more hardware components that provide the physical structure that performs processes related to wireless communication (e.g., signal reception and/or signal transmission) and signal processing (e.g., processing a received signal and/or processing a signal for transmission). The communication and processing circuitry 941 may further be configured to execute communication and processing instructions 951 (e.g., software) stored, for example, on the computer-readable medium 906 to implement one or more functions described herein.

In some aspects of the disclosure, the processor 904 may include input signal circuitry 942 configured for various functions, including, for example, obtaining an input signal representative of a current passing through a first circuit. The input signal circuitry 942 may further be configured to execute input signal instructions 952 (e.g., software) stored, for example, on the computer-readable medium 906 to implement one or more functions described herein.

In some aspects of the disclosure, the processor 904 may include convolutional neural network model circuitry 943 configured for various functions, including, for example, applying the input signal to one or more input nodes of a second circuit, different from the first circuit, and configured according to a convolutional neural network model. The convolutional neural network model circuitry 943 may further be configured to configure the convolutional neural network as a plurality of building blocks, and to configure each building block as: a one-dimensional pointwise convolution with one-half of all filters at a first sub-layer, wherein each of the one-half of all filters at the first sub-layer is a 1×1 matrix; a one-dimensional depthwise convolution with one-half of all filters at a second sub-layer followed by a max pooling at the second sub-layer, wherein each of the one-half of all filters at the second sub-layer is 5×1 matrix; and a one-dimensional pointwise convolution with all filters at a third sub-layer followed by a one-dimensional stride at the third sub-layer, wherein each of the all filters at the third sub-layer is a 2×1 matrix. According to some aspects, the convolutional neural network model is a student convolutional neural network model, and the student convolutional neural network model is trained by a pretrained teacher convolutional neural network model. According to some aspects, prior to applying the input signal to one or more input nodes of a second circuit, the convolutional neural network model circuitry, in combination with, for example, the communication and processing circuitry 941, may be configured to normalize the input signal. In some examples, the input signal may be normalized using a min-max normalization technique. In some examples, the normalized input signal may be converted from a time domain signal to a frequency domain signal and the frequency domain signal may be applied to the one or more input nodes of the second circuit. In some examples, the normalized input signal may be subjected to time domain feature extraction and a resultant time domain feature extracted signal may be applied to the one or more input nodes of the second circuit. The convolutional neural network model circuitry 943 may further be configured to execute convolutional neural network model instructions 953 (e.g., software) stored, for example, on the computer-readable medium 906 to implement one or more functions described herein.

In some aspects of the disclosure, the processor 904 may include output node driving circuitry 944 configured for various functions, including, for example, driving one or more output nodes of the second circuit according to a detection by the convolutional neural network model of an arc fault in the current passing through the first circuit, the one or more output nodes driven to: first value indicative of an absence of the detection of the arc fault in the current passing through the first circuit, or a second value indicative of the detection of the arc fault in the current passing through the first circuit. The output node driving circuitry 944 may further be configured to execute output node driving instructions 954 (e.g., software) stored on the computer-readable medium 906 to implement one or more functions described herein.

In some aspects of the disclosure, the processor 904 may include switch driving circuitry 945 configured for various functions, including, for example, driving a switch (e.g., switch 915 or FIG. 9, switch 126 of FIG. 1) having an input terminal (e.g., 130 of FIG. 1), an output terminal (e.g., 120 of FIG. 1), and a control terminal (e.g., 132 of FIG. 1), the control terminal coupled to the convolutional neural network output node (e.g., 131 of FIG. 1) and configured to cause the switch to: impede the current (e.g., 133 of FIG. 1) between the input terminal and the output terminal in response to the first value being present at the convolutional neural network output node, or pass the current between the input terminal and the output terminal in response to the second value being present at the convolutional neural network output node. The switch driving circuitry 945 may further be configured to execute switch driving instructions 955 (e.g., software) stored on the computer-readable medium 906 to implement one or more functions described herein.

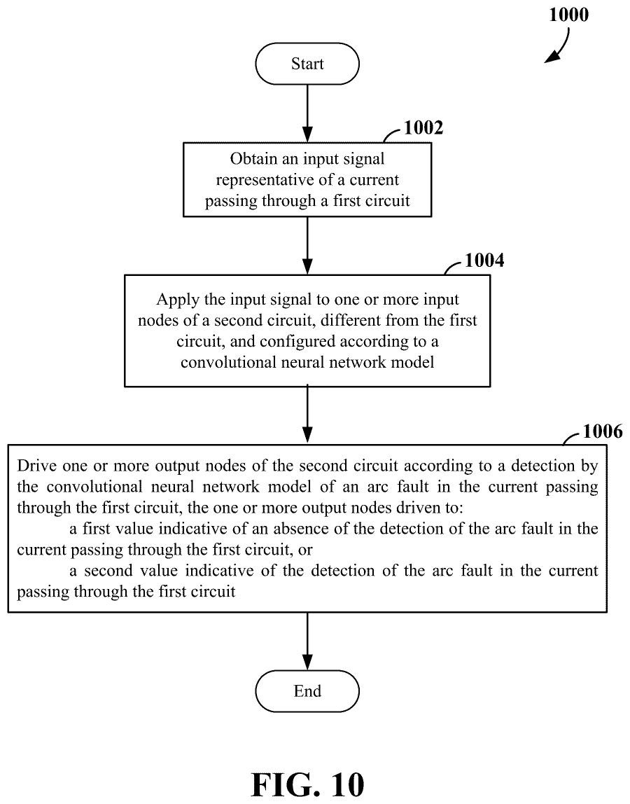

FIG. 10 is a flow chart illustrating an example process 1000 (e.g., a method) at an apparatus in accordance with some aspects of the disclosure. As described below, some or all illustrated features may be omitted in a particular implementation within the scope of the present disclosure, and some illustrated features may not be required for implementation of all embodiments. In some examples, the process 1000 may be carried out by the apparatus 900, as shown and described in connection with FIG. 9. The apparatus 900 may be similar to, for example, any of the apparatus, devices, objects, or portions thereof as shown and described in connection with FIG. 1, 2, 6, 7, 8A, 8B, and/or 9. In some examples, the process 1000 may be carried out by any suitable apparatus or means for carrying out the functions or algorithm described below.

At block 1002, the apparatus may obtain an input signal representative of a current passing through a first circuit. For example, the input signal circuitry 942, as shown and described in connection with FIG. 9, may provide a means for obtaining an input signal representative of a current passing through a first circuit. According to some aspects, prior to applying the input signal to one or more input nodes of a second circuit, the input signal is normalized. In some examples, the input signal may be normalized using a min-max normalization technique. In some examples, the normalized input signal may be converted from a time domain signal to a frequency domain signal and the frequency domain signal may be applied to the one or more input nodes of the second circuit. In some examples, the normalized input signal may be subjected to time domain feature extraction and a resultant time domain feature extracted signal is applied to the one or more input nodes of the second circuit.

At block 1004, the apparatus may apply the input signal to one or more input nodes of a second circuit, different from the first circuit, and configured according to a convolutional neural network model. For example, the convolutional neural network model circuitry 943, as shown and described in connection with FIG. 9, may provide a means for applying the input signal to one or more input nodes of a second circuit, different from the first circuit, and configured according to a convolutional neural network model. According to some aspects, the convolutional neural network may be configured as a plurality of building blocks. In some examples, each building block may be configured as a concatenation of, a series of, sub-layers. In some examples, the sub-layers may include a one-dimensional pointwise convolution with one-half of all filters at a first sub-layer, wherein each of the one-half of all filters at the first sub-layer is a 1×1 matrix; followed by a one-dimensional depthwise convolution with one-half of all filters at a second sub-layer followed by a max pooling at the second sub-layer, wherein each of the one-half of all filters at the second sub-layer is 5×1 matrix; and followed by a one-dimensional pointwise convolution with all filters at a third sub-layer followed by a one-dimensional stride at the third sub-layer, wherein each of the all filters at the third sub-layer is a 2×1 matrix. According to some aspects, the convolutional neural network model may be a student convolutional neural network model, and the student convolutional neural network model may be trained by a teacher convolutional neural network model. The training may involve the use of a knowledge distillation technique to transfer knowledge distilled from the teacher model to the student model.

At block 1006, the apparatus may drive one or more output nodes of the second circuit according to a detection by the convolutional neural network model of an arc fault in the current passing through the first circuit, the one or more output nodes driven to: a first value indicative of an absence of the detection of the arc fault in the current passing through the first circuit, or a second value indicative of the detection of the arc fault in the current passing through the first circuit. For example the output node driving circuitry 944, alone or in combination with the switch driving circuitry 945, as shown and described in connection with FIG. 9, may provide a means for driving one or more output nodes of the second circuit according to a detection by the convolutional neural network model of an arc fault in the current passing through the first circuit, the one or more output nodes driven to: a first value indicative of an absence of the detection of the arc fault in the current passing through the first circuit, or a second value indicative of the detection of the arc fault in the current passing through the first circuit. According to some aspects, one or more current sensors may be coupled to one or more processors and each of the one or more current sensors may be configured to derive a respective voltage waveform representative of the current flowing through the first circuit in the time domain. Furthermore, one or more sampling circuits, or analog-to-digital conversion circuits, coupled to the one or more current sensors may be configured to sample the respective voltage waveform at a predetermined sampling rate to produce the input signal. According to some aspects, a switch having an input terminal, an output terminal, and a control terminal, where the control terminal may be coupled to a convolutional neural network output node or a switch driver, and the signal driving the control terminal of the switch may be configured to cause the switch to: impede the current (133, FIG. 1) between the input terminal and the output terminal in response to the first value being present at the convolutional neural network output node, or pass the current between the input terminal and the output terminal in response to the second value being present at the convolutional neural network output node.

Thereafter, the process 1000 may end.

The convolutional neural network model that is configured in hardware and sold to consumers, may be the student convolutional neural network model 702. The student convolutional neural network model 702 may be used to detect arc faults in circuits, such as, but not limited to the first circuit 101 as shown and described in connection with FIG. 1.

According to some examples, an output layer of the student convolutional neural network model 702 may have a softmax configuration, which may be used to convert the logits of each class, zᵢ, into a probability, pᵢ by comparing the logits of each class with other logits. The value of pᵢ may be expressed as follows,

$${p}_{i} = \frac{{e}^{\frac{{z}_{i}}{T}}}{{\sum }_{j} {e}^{\frac{{z}_{j}}{T}}} \qquad ( 1 )$$

where T is the temperature. The value of T is usually set to 1. If the value of T is increased to a higher value, a softer distribution of probability i obtained over other classes.

The teacher model may be trained with a transfer set by setting a high value of T in its softmax function. The knowledge is then transferred to the distilled model by training using a soft target distribution in the transfer set for each case. For known correct labels of all or part of the transfer sets, this technique can be improved by training the distilled model using a weighted mean of two objective functions to generate the exact labels. The first, where T is the temperature. The value of T is usually set to 1. If the value of T is increased to a higher value, a softer distribution of probability is obtained over other classes.

The teacher convolutional neural network model 701 may be trained with a transfer set by setting a high value of T in its softmax function. The knowledge is then transferred to the distilled model by training it using a soft target distribution in the transfer set for each case. For known correct labels of all or part of the transfer sets, this technique can be improved by training the distilled model by using a weighted mean of two objective functions to generate the exact labels. The first objective function, the cross-entropy having soft targets in the distilled model, is computed by using the same high temperature as used by the teacher model for a soft target. The 2nd objective function is the cross-entropy with the correct labels which is computed by using the same Logits as used in softmax function of the distilled model. The temperature, however, is now set to 1. The model produces a soft probability of qᵢ and it has logits uᵢ. The cross-entropy loss can be defined as

$$C ( x ) = - {\sum }_{i} {q}_{i} ( x ) log {p}_{i} ( x ) \qquad ( 2 )$$

where x is the input feature. The cross-entropy gradient

$$\frac{\partial c}{\partial zi} ,$$

of the distilled model can be expressed as

$$\begin{matrix}\frac{\partial C}{\partial {z}_{i}} & = \frac{\partial }{\partial {z}_{i}} ( - {\sum }_{i} {q}_{i} log {p}_{i} ) \\ & = - {q}_{i} \frac{1}{{p}_{i}} ( \frac{\partial {p}_{i}}{\partial {z}_{i}} ) \\ & = - {q}_{i} \frac{1}{{p}_{i}} \frac{\partial {p}_{i}}{\partial {z}_{i}} ( \frac{{e}^{\frac{{z}_{i}}{T}}}{{\sum }_{j} {e}^{\frac{{z}_{j}}{T}}} ) \\ & = - {q}_{i} \frac{1}{{p}_{i}} [ \frac{\frac{1}{T} {e}^{\frac{{z}_{i}}{T}} {\sum }_{j} {e}^{\frac{{z}_{j}}{T}} - {\frac{1}{T}}^{{( {e}^{\frac{{z}_{i}}{T}} )}^{2}}}{{( {\sum }_{j} {e}^{\frac{{z}_{j}}{T}} )}^{2}} ] \\ & = - {q}_{i} \frac{1}{{p}_{i}} \frac{1}{T} [ \frac{{e}^{\frac{{z}_{i}}{T}}}{{\sum }_{j} {e}^{\frac{{z}_{j}}{T}}} - {( \frac{{e}^{\frac{{z}_{i}}{T}}}{{\sum }_{j} {e}^{\frac{{z}_{j}}{T}}} )}^{2} ] \\ & = \frac{1}{T} ( {p}_{i} - {q}_{i} ) \\ & = \frac{1}{T} ( \frac{{e}^{\frac{{z}_{i}}{T}}}{{\sum }_{j} {e}^{\frac{{z}_{j}}{T}}} - \frac{{e}^{\frac{{u}_{i}}{T}}}{{\sum }_{j} {e}^{\frac{{u}_{j}}{T}}} )\end{matrix} \qquad ( 3 )$$

where uᵢ denotes the logits of the teacher model and qᵢ indicates the possibilities of the soft targets with a transfer train temperature of T. For the high temperature, equation (3) can be approximated as given below:

$$\frac{\partial c}{\partial {z}_{i}} \approx \frac{1}{T} ( \frac{1 + \frac{{z}_{i}}{T}}{N + {\sum }_{j} {e}^{\frac{{z}_{j}}{T}}} - \frac{1 + \frac{{u}_{i}}{T}}{N + {\sum }_{j} {e}^{\frac{{u}_{j}}{T}}} ) \qquad ( 4 )$$

Assuming the logits to have zero mean for each transfer case, Σⱼzᵢ=Σⱼuᵢ=0 where, (zero-mean hypothesis), equation (4) can be simplified further to:

$$\frac{\partial C}{\partial {z}_{i}} \approx \frac{1}{{NT}^{2}} ( {z}_{i} - {u}_{i} ) \qquad ( 5 )$$

Given that the logits are zero mean for each transfer case, the distillation is considered equivalent to minimize

$$\frac{1}{2} {( {z}_{i} - {v}_{i} )}^{2}$$

in the high limit or the temperature T.

The distillation pays little attention to logits matching at low values of the temperature. Therefore, the loss function of the teacher model is completely unconstrained for training and could be noisy. Furthermore, a negative value of the logits furnishes useful information regarding the knowledge gathered by the teacher model.

Both the teacher network and the student network architectures of convolutional neural network described herein utilize three of the first building block 601, as shown and described in connection with FIG. 6, followed by three fully connected (FC) layers. However, the number of filters (channels) in the teacher network is 256, 512, and 512 in the three main blocks (the first building block 601), respectively. The number of neurons is 128, 64, and 8 in the following three FC layers, respectively. The student network, on the other hand, is designed to have very few filters and neurons in the corresponding layers of the teacher model. It has only 16, 32, and 32 filters in the first three of the first building block 601 as shown and described in connection with FIG. 6, and is followed by 64, 32, and 8 neurons in the three FC layers, respectively. The number of filters in the student network is chosen and fine-tuned so as to keep the architecture simpler as well as optimized without sacrificing accuracy. The complete architectures of the teacher and the student network are illustrated in FIG. 8A and FIG. 8B, respectively. The data flow of the student model is tabulated in Table II. The convolutional neural network model described herein may be constructed to obtain multi-fold benefits.

One benefit is the reduction in computational complexity as well as kilo floating point operations per second (kFLOPs) by using an efficient building block to build a shallow network. Another way of reducing computational complexity is by compressing the model using the knowledge distillation method. Therefore, the number of trainable parameters is the lowest as compared to other simplified models discussed below.

An aggressive bottleneck for data flow through a network can cause a huge reduction of significant features along the way. This might have a destructive effect when applied to a smaller deep model.

TABLE II

| Baseline | | | | | | ArcNet-Lite | |
|---|---|---|---|---|---|---|---|
| (Traditional CNN) | | Mobile-ArcNet | | Efficient-ArcNet | | (Student Model) | |
| Layers | Params | Layers | Params | Layers | Params | Layers | Params |
| 5 × 1 × 96 + | 576 | 5 × 1 × 96 + | 576 | 1 × 1 × 48 | 96 | 1 × 1 × 8 | 16 |
| mp of 2 | | mp of 2 | | dw 5 × 1 + | | dw 5 × 1 + | |
| | | | | mp of 2 | 2592 | mp of 2 | 112 |
| | | | | 2 × 1 × 96 + | | 2 × 1 × 16 + | |
| | | | | stride of 2 | 9312 | stride of 2 | 272 |
| 5 × 1 × 128 + | 61568 | dw 5 × 1 + | 12896 | 1 × 1 × 64 | 9208 | 1 × 1 × 16 | 272 |
| mp of 2 | | stride of 2 | | dw 5 × 1 + | | dw 5 × 1 + | |
| | | 1 × 1 × 128 | 16512 | mp of 2 | 4480 | mp of 2 | 352 |
| | | | | 2 × 1 × 128 + | | 2 × 1 × 32 + | |
| | | | | stride of 2 | 16512 | stride of 2 | 1056 |
| 5 × 1 × 128 + | 82048 | dw 5 × 1 + | 17152 | 1 × 1 × 64 | 4480 | 1 × 1 × 16 | 528 |
| mp of 2 | | stride of 2 | | dw 5 × 1 + | | dw 5 × 1 + | |
| | | 1 × 1 × 128 + | 16512 | mp of 2 | 16512 | mp of 2 | 352 |
| | | mp of 4 | | 2 × 1 × 128 + | | 2 × 1 × 32 + | |
| | | | | stride of 2 | 8256 | stride of 2 | 1056 |
| FC (64, 32, 8) | 174440 | FC (64, 32, 8) | 41568 | FC (64, 32, 8) | 10600 | FC (64, 32, 8) | 4,456 |
| Total | 318,016 | | 107,016 | | 79,048 | | 8,472 |
| Params | | | | | | | |

Table II identifies the network architecture of ArcNet-Lite (Student Model) (last column) and compares that network architecture with the network architectures of a baseline model, Mobile-ArcNet, and Efficient-ArcNet (EffNet).

The term “FC (64, 32, 8)” refers to three fully connected (FC) layers having 64, 32, and 8 neurons, respectively. The last FC layer has eight neurons for eight output classes (arc and normal current of 4 load groups). Depthwise convolution and max pooling layers are denoted ‘dw’ & ‘mp’ respectively.

In Table II, the baseline (Traditional CNN column) may be exemplified by the fifth building block 605 of FIG. 6E, for example. In Table II, above, in the architecture of Efficient-ArcNet, a bottleneck factor of 4 was noticed in the last building block row for the first sub-layer identified as 1×1×64 with 4480 parameters. In contrast, in the architecture of ArcNet-Lite (Student Model), a bottleneck factor of at most 2 was noticed in the last building block row for the first sub-layer identified as 1×1×16 with 528 parameters. This consideration yields a smoother data flow and makes the model more efficient. Besides, narrower models do not have the luxury to have a larger reduction factor because of the inadequate availability of filters.

A baseline model, using conventional CNN layers, is designed following the structure, number of neurons, and filters of the EffNet model. The Mobile-ArcNet model is also designed following a similar network architecture. There is a similarity in the number of filters in these three models except ArcNet-Lite. The purpose of Mobile-ArcNet and EffNet models was to make the model slimmer and more efficient. However, the full scope of the model compression technique is not utilized there. A brief discussion of those networks is provided below.

1. Baseline Model: The Baseline model is designed using only the conventional convolutional neural network layers (e.g., fifth building block 605 of FIG. 6E). It does not include any special efficient building block in it. The purpose of designing this model is to check and verify the performance gain of the proposed efficient model over the conventional CNN-based model. The Baseline model consists of three convolution layers, each of them followed by a max pooling layer of size 2×1. The convolution layers have 96, 128, and 128 filters, respectively. At the end of the third max pooling layer, there are three fully connected (FC) layers consisting of 64, 32, and 8 neurons, respectively. Among the three FC layers, the last one is the output layer which provides arc and normal load current classification of four different load groups. The data flow and architecture of the baseline model are depicted in Table II. Because of using only conventional CNN blocks in the model, the total number of parameters becomes the highest for the baseline model.

2. Mobile-ArcNet Model: Mobile-ArcNet is built with the building block as is shown in FIG. 6B. Because a depthwise convolutional layer is used in the building block followed by a pointwise convolution, it reduces the computation compared to the conventional baseline model. The Mobile-ArcNet architecture is made up of a ID CNN layer of 96 filters (5×1) followed by a max pooling layer of pooling size 2×1. A Mobile-ArcNet building block is not employed at the input convolution layer to comply with the architectural similarity of MobileNet. The next two layers have Mobile-ArcNet building blocks having filters of 128 in each layer. Each time the filter size has been kept the same (5×1). A stride of 2 has been used. After the 3rd layer, a max pooling layer of size (4×1) has been used. At the end of the 3 convolution layers, we used 3 fully connected layers of 64, 32, and 8 filters. The data flow of Mobile-ArcNet is shown in Table II. The total number of trainable parameters in the Mobile-ArcNet block gets much lower than in the conventional Baseline model. A considerable reduction in the trainable parameters also reduces the computational complexity. This network was designed to obtain the maximum possible accuracy and lowest possible complexity.

3. Efficient-ArcNet Model: The Efficient-ArcNet Model is composed using the third building block 603 as shown and described in connection with FIG. 6C. Compared to the ArcNet-lite model the Efficient-ArcNet model gets competitive advantages because of its lightweight and efficient structure. It has three efficient convolutional neural network (CNN) layers annexed with three fully connected layers having 96, 128, and 128 neurons, respectively. It used a depthwise convolutional structure. Moreover, it uses a max pooling layer in its block, which reduces the computational complexity further than that of Mobile-ArcNet. As the model used a pointwise convolution at the beginning, it does decrease the computation there. The use of a max pooling layer in the block further reduces the computation size in the beginning and that follows to the next adjacent layers. Thus, it gets an added benefit compared to the Mobile-ArcNet structure. The complete architecture of Efficient-ArcNet along with the data flow has been tabulated in Table II. Even though the Efficient-ArcNet model has high accuracy, it has not used the full scope of the network compression technique. Moreover, it has used an aggressive reduction of features along the way which is highlighted in red in Table II. For slimmer models, this huge bottleneck (factor of 4) may have a destructive effect.

All the loads are grouped into 4 major groups as per the characteristics of the load currents. The sampling rate of the data is 10 kHz. The total sample in the database is 30151 which is when split at a ratio of 75:15:10 for training, testing, and validation set. This gives 22607, 4513, and 3031 samples for training, testing, and validation, respectively. Before the training, all the labels are converted into corresponding OneHot encoding. The input to the model is the raw current and no preprocessing other than min-max normalization of the current data is performed before feeding the data to the proposed model. The ArcNet-Lite teacher model is trained for 300 epochs, with a batch size of 100, the learning rate is set to 0.001 with Adam Optimizer. The distiller model (student) is also trained with 300 epochs using the Adam optimizer. The alpha value and the temperature are set to 0.5 and 20, respectively. The observed loss confirms the model is not overfitted. The cumbersome Teacher model has a higher number of neurons and filters in its layers so that it can train well to achieve good classification accuracy. Then it can transfer its knowledge to the tiny student model using the knowledge distillation technique.

Mobile-ArcNet and Efficient-ArcNet models are trained with 250 epochs each using an adaptive learning rate. During the training of the model, the Adam optimizer is used with an initial learning rate of 0.001 and a minimum learning rate is set to 0.00001. The learning rate is reduced by monitoring the validation loss with a patience of 10 and a factor of 0.1. The batch size was set to 100 for training. All the models, including the proposed ArcNet-Lite model, are trained in the TensorFlow platform of Keras. Loss is calculated using “categorical cross entropy.” The activation function used in the convolution layer is Rectified Linear Unit (ReLU). In the output layer, the softmax activation function is employed. All the hyperparameters are fine-tuned for the best possible result. The ArcNet-Lite model is trained using a mixed-precision system (a combination of 16-bit and 32-bit floating points). The data samples are converted into a 16-bit floating point before training to get a computational advantage.

TABLE III

| | | Arc | | | | Runtime |
|---|---|---|---|---|---|---|
| | 8 Class | Classification | | | | per |
| | Accuracy | Accuracy | Trainable | | | Sample |
| Model¹ | (%) | (%) | Parameters | kFLOPs | Factor | (ms) |
| Baseline | 98.96 | 99.22 | 318.63k | 19205.4 | 1 | 3.27 |
| Mobile- | 99.00 | 99.29 | 107.02k | 4542.93 | 0.24 | 1.43 |
| ArcNet | | | | | | |
| ArcNet- | — | 94.63 | 14.62k | 379.52 | 0.02 | 1.00² |
| Lite_FFT³ | | | | | | |
| ArcNet- | 98.85 | 99.31 | 8.4k | 182.27 | 0.01 | 0.20 |
| Lite | | | | | | |
| (Proposed)⁴ | | | | | | |

¹All models are optimized using TF-Lite optimization tool. Data normalization per sample takes 0.8 μs.
²Time taken to perform FFT per sample is 0.67 ms and inference time is 0.33 ms.
³Input to the model is 1D data in the frequency domain (40 kHz).
⁴Input to the model is raw data with Min-Max normalization.

Table III provides experimental results obtained from the ArcNet-Lite convolutional neural network model in comparison to the experimental results obtained for a baseline, Mobile-ArcNet, and ArcNet-Lite FFT convolutional neural network models.

This section describes the experimental results of the ArcNet-Lite model along with Baseline, and Mobile-ArcNet models. Each of the models has been trained and tested using the same database. For these models, the input is Min-Max normalized raw current. However, to check the result and performance of the ArcNet-Lite model for frequency domain data as input we tested the model using 40 kHz FFT data in the input. This model is referred to herein as ArcNet-Lite_FFT.

The baseline model has only conventional convolutional blocks, hence the number of trainable parameters is the highest among them. Although the model has used max pooling layer, the conventional CNN blocks are not computationally effective. The Mobile-ArcNet model has a higher number of trainable parameters (107.2 k) than the ArcNet-Lite. It is to be noted that none of the Baseline or Mobile-ArcNet models was not trained using knowledge distillation technique. We trained the ArcNet-Lite student model using knowledge distillation method where the knowledge is transferred to the student by the cumbersome teacher model which is better in learning features from the arc and normal samples. The ArcNet-Lite model is trained and tested separately using the frequency domain data and raw input current data, respectively. When the ArcNet-Lite_FFT model is fed with frequency domain data as input, it gives poor arc fault detection accuracy once tested. Although it takes only 0.33 ms to infer the sample, the data preprocessing (FFT) time is larger (0.67 ms) compared to the prediction time. The higher the FLOPs, the more complex is the computation of the model. Compared to the kFLOPs of the Baseline model, Mobile-ArcNet has a factor of 0.24, ArcNet-Lite_FFT has a factor of 0.02, and the ArcNet-Lite model has a factor of only 0.01. ArcNet-Lite has only 182.27 kFLOPs of computational burden. This indicates that the proposed ArcNet-Lite model has the least computational complexity and hence it is lightweight. The complete results are tabulated in Table III, above.

In terms of accuracy, the Baseline model has the lowest accuracy for arc fault detection (99.22%). ArcNet-Lite, on the other hand, provides a little better or comparable accuracy (99.31%). Moreover, the ArcNet-Lite model is the simplest, and tiniest among all the models and hence most suitable for practical application. Besides, the accuracy is comparable with other models.

Using the ArcNet-Lite model, the load classification accuracy as well as arc fault accuracy are determined. The confusion matrix is depicted in Table IV which shows percent accuracy for 8 class classifications of different load groups along with the number of misclassifications. Even numbered labels indicate arc fault classes and odd-numbered labels refer to the normal current. The resistive loads have a high arc fault classification accuracy, arc faults of gas discharge lamp loads showed the least classification accuracy (87.50%). This is because of the nature of the GDL loads. The normal load currents of GDL loads resemble an arc fault current in some cases. Also, it is evident from the result that a major portion of the GDL arc loads has been confused with the resistive arc (10.23%). Overall, arc fault detection accuracy for binary classification has been calculated by summing up all the correctly classified arc faults and dividing the result by the sum of all the test samples. The precision, recall, and binary classification accuracy for arc and normal current samples are determined irrespective of load classification. The precision and recall matrix of the ArcNet-Lite model is shown in Table V and it is computed with the help of Table IV. The correctly classified arc samples are summed up and the normal samples which are correctly classified as normal are also added up. Similarly, the misclassified arc and misclassified normal samples are summed up individually to compute the precision and recall matrix. The overall accuracy is calculated using the precision and recall matrix. A high precision and recall value of the model indicates its practicability and that it has a low value for false-positive and false-negative rates.

TABLE IV

| | Label | 0 | 1 | 2 | 3 | 4 | 5 | 6 | 7 |
|---|---|---|---|---|---|---|---|---|---|
| Resistive | 0 | 617 | 11 | 3 | 0 | 0 | 0 | 0 | 1 |
| loads | | 97.63% | 1.74% | 0.47% | 0.00% | 0.00% | 0.00% | 0.00% | 0.16% |
| | 1 | 6 | 1259 | 0 | 0 | 0 | 0 | 0 | 3 |
| | | 0.47% | 99.29% | 0.00% | 0.00% | 0.00% | 0.00% | 0.00% | 0.24% |
| Motor Loads | 2 | 1 | 0 | 280 | 2 | 1 | 0 | 1 | 0 |
| | | 0.35% | 0.00% | 98.25% | 0.70% | 0.35% | 0.00% | 0.35% | 0.00% |
| | 3 | 0 | 0 | 0 | 667 | 0 | 0 | 0 | 0 |
| | | 0.00% | 0.00% | 0.00% | 100.00% | 0.00% | 0.00% | 0.00% | 0.00% |
| Power | 4 | 1 | 0 | 2 | 0 | 421 | 9 | 0 | 0 |
| electronics enabled & | | 0.23% | 0.00% | 0.46% | 0.00% | 97.23% | 2.08% | 0.00% | 0.00% |
| SMPS loads | 5 | 0 | 0 | 0 | 0 | 0 | 677 | 0 | 0 |
| | | 0.00% | 0.00% | 0.00% | 0.00% | 0.00% | 100% | 0.00% | 0.00% |
| Gas Discharge | 6 | 9 | 0 | 0 | 1 | 0 | 0 | 77 | 1 |
| lamps | | 10.23% | 0.00% | 0.00% | 1.14% | 0.00% | 0.00% | 87.50% | 1.14% |
| | 7 | 0 | 0 | 0 | 0 | 0 | 0 | 0 | 463 |
| | | 0.00% | 0.00% | 0.00% | 0.00% | 0.00% | 0.00% | 0.00% | 100% |

Table IV presents a confusion matrix for eight class classifications (see eight labels 0-7) using an ArcNet-Lite convolutional neural network model according to aspects described herein. A confusion matrix, also known as an error matrix, is a table that summarizes the performance of a classification model in machine learning. It compares the number of ground truth instances of a class to the number of predicted instances and can help identify which classes are most often misclassified.

Even numbered labels are arc classes (i.e., where the current flowing through the circuit under test includes arc signatures) and odd numbered labels represent normal classes (i.e., where the current flowing through the circuit under test has an absence of arc signatures; that is, the current is a normal or nominal current without exhibiting or including any evidence of arcing in association with the circuit).

The ArcNet-Lite model is simpler in structure compared to the baseline, and Mobile-ArcNet models. The cumbersome teacher model is created as a very large model in size so that it can learn the arc features effectively and with high accuracy. This allowed making the student model very lightweight because the teacher model transferred its knowledge to the tinier and narrower student model using the knowledge distillation technique. It is to be noted that, in the Mobile-ArcNet model, the first layer is not replaced with a depthwise layer. However, in ArcNet-Lite model the first layer is also replaced with the EffNet design blocks and hence the computational burden reduces a lot for the forthcoming layers. Although the Efficient-ArcNet model is lightweight compared to Mobile-ArcNet, it has a bottleneck factor of 4 as used in ShuffleNet architecture. The ArcNet-Lite model, on the other hand, used a maximum bottleneck factor of 2. This allowed smoother data flow. Besides getting the advantage of using bottleneck structure and depthwise separable convolution in the model, the use of the teacher-student knowledge distillation technique in ArcNet-Lite furnishes the model with a step towards the model compression and acceleration. The way the ArcNet-Lite block is structured, the number of kFLOPs is also reduced significantly. The ArcNet-Lite model gets a multi-fold benefit and achieves not only a lightweight model structure but also an exceedingly high performance in detecting series AC arc faults with high accuracy. Therefore, the computation cost, as well as runtime per sample, is the least for the proposed model.

TensorFlow Lite (TF-Lite) is an open-source deep learning framework. TF-Lite is a set of tools that can help us to run TensorFlow models in low-power edge computing devices such as microcontrollers or mobile devices having limited resources and memory. It also provides us an opportunity to optimize a model to get a low binary size and low latency. The ArcNet-Lite student model is optimized using a TF-lite interpreter and transformed into a TF-lite model. TensorFlow Python application programming interface (API) is used for the optimization and conversion of the model. The TF-lite version of the model has optimized and improved binary size (only 49 kB, compared to the unoptimized binary size of 600 kB) and is much more efficient to run in edge devices. After the conversion, the ArcNet-Lite model is implemented in Raspberry PI 4B to check its capability of real time operation.

The TF-Lite model is first loaded into the system to get the interpreter. Then the tensors are allocated using the interpreter to get the input and output details of the converted model. Finally, the input and output details are applied to test the sample test sets. The model is tested in Raspberry PI 4B five times using all the test samples and the results are recorded in Table VI. The average inference time per sample is only 0.20 ms for the optimized ArcNet-Lite model. In addition, the accuracy was not dropped due to this optimization. The test time indicated here includes the time taken to fetch a sample, Min-Max normalization, fetch the corresponding label, and the time taken to test the sample. Table V, below, presents the precision, recall, and overall accuracy of the ArcNet-Lite convolutional neural network model. Table VI, below, presents experimental data representing the runtime per sample (given as the average, largest, and smallest runtimes plus variance) for the ArcNet-Lite convolutional neural network model implemented on a Raspberry PI 4B MCU.

TABLE V

| | | Predicted Class | | |
|---|---|---|---|---|
| | | Arc | Normal | Total |
| Actual Class | Arc | 1413 | 25 | 1438 |
| | Normal | 6 | 3069 | 3075 |
| | Total | 1419 | 3094 | 4513 |

| | |
|---|---|
| Precision | 99.58% |
| Recall | 98.26% |
| Overall accuracy | 99.31% |

TABLE VI

| | Average | Largest | Smallest | Variance |
|---|---|---|---|---|
| | runtime | runtime | runtime | of |
| Sample No. | (ms) | (ms) | (ms) | runtime |
| 1 | 0.201 | 1.24 | 0.199 | 0.0004 |
| 2 | 0.20 | 1.176 | 0.2 | 0.0002 |
| 3 | 0.202 | 1.201 | 0.199 | 0.0003 |
| 4 | 0.299 | 1.300 | 0.2 | 0.0004 |
| 5 | 0.203 | 1.258 | 0.198 | 0.00035 |
| Average | 0.20 | 1.217 | 0.198 | 0.000365 |

Besides, the reported runtime (only 0.2 ms per sample) is the lowest compared to the other methods. ArcNet-Lite used 3-stage model simplification in the algorithm. The first simplification is at the architecture level to reduce the computational burden. In the second stage, the model is compressed using the knowledge distillation method to reduce the size of the model and improve its performance. Finally, the model is optimized using TF-Lite to get a reduced binary size and low latency to implement in resource-limited MCU. Therefore, ArcNet-Lite has low computation and achieved excellent performance when run in an edge device.

Of course, in the above examples, the circuitry included in the one or more processors of the apparatus, generally represented by the processor 904 of the apparatus 900 of FIG. 9, is merely provided as an example. Other means for carrying out the described processes or functions may be included within various aspects of the present disclosure, including but not limited to the instructions stored in the one or more computer-readable media, generally represented by the computer-readable medium 906 and/or the memory 905 of the apparatus 900 of FIG. 9, or any other suitable apparatus or means described in any one of the FIGS. 1, 2, 5, 6, 7, 8A, 8B, and/or 9 utilizing, for example, the processes and/or algorithms described herein in relation to FIGS. 1-10.

Within the present disclosure, the word “exemplary” is used to mean “serving as an example, instance, or illustration.” Any implementation or aspect described herein as “exemplary” is not necessarily to be construed as preferred or advantageous over other aspects of the disclosure. Likewise, the term “aspects” does not require that all aspects of the disclosure include the discussed feature, advantage, or mode of operation. The term “coupled” is used herein to refer to the direct or indirect coupling between two objects. For example, if object A physically touches object B, and object B touches object C, then objects A and C may still be considered coupled to one another-even if they do not directly physically touch each other. For instance, a first object may be coupled to a second object even though the first object is never directly physically in contact with the second object. The terms “circuit” and “circuitry” are used broadly and intended to include both hardware implementations of electrical devices and conductors that, when connected and configured, enable the performance of the functions described in the present disclosure, without limitation as to the type of electronic circuits, as well as software implementations of information and instructions that, when executed by a processor, enable the performance of the functions described in the present disclosure.

One or more of the components, steps, features, and/or functions illustrated in FIGS. 1-10 may be rearranged and/or combined into a single component, step, feature, or function or embodied in several components, steps, or functions. Additional elements, components, steps, and/or functions may also be added without departing from novel features disclosed herein. The apparatus, devices, and/or components illustrated in FIGS. 1-10 may be configured to perform one or more of the methods, features, or steps described herein. The novel algorithms described herein may also be efficiently implemented in software and/or embedded in hardware.

It is to be understood that the specific order or hierarchy of steps in the methods disclosed is an illustration of exemplary processes. Based upon design preferences, it is understood that the specific order or hierarchy of steps in the methods may be rearranged. The method claims present elements of the various steps in a sample order and are not meant to be limited to the specific order or hierarchy presented unless specifically recited therein. While some examples illustrated herein depict only time and frequency domains, additional domains such as a spatial domain are also contemplated in this disclosure.

The previous description is provided to enable any person skilled in the art to practice the various aspects described herein. Various modifications to these aspects will be readily apparent to those skilled in the art, and the generic principles defined herein may be applied to other aspects. Thus, the claims are not intended to be limited to the aspects shown herein but are to be accorded the full scope consistent with the language of the claims, wherein reference to an element in the singular is not intended to mean “one and only one” unless specifically so stated, but rather “one or more.” Unless specifically stated otherwise, the term “some” refers to one or more.

The word “obtain” as used herein may mean, for example, acquire, calculate, construct, derive, determine, receive, and/or retrieve. The preceding list is exemplary and not limiting. All structural and functional equivalents to the elements of the various aspects described throughout this disclosure that are known or later come to be known to those of ordinary skill in the art are expressly incorporated herein by reference and are intended to be encompassed by the claims. Moreover, nothing disclosed herein is intended to be dedicated to the public regardless of whether such disclosure is explicitly recited in the claims. No claim element is to be construed under the provisions of 35 U.S.C. § 112 (f) unless the element is expressly recited using the phrase “means for” or, in the case of a method claim, the element is recited using the phrase “step for.”

As used herein, the term “determine” or “determining” encompasses a wide variety of actions and, therefore, “determining” can include calculating, computing, processing, deriving, investigating, looking up (such as via looking up in a table, a database, or another data structure), inferring, ascertaining, measuring, and the like. Also, “determining” can include receiving (such as receiving information), accessing (such as accessing data stored in memory), transmitting (such as transmitting information) and the like. Also, “determining” can include resolving, selecting, obtaining, choosing, establishing, and other similar actions.

As used herein, a phrase referring to “at least one of” a list of items refers to any combination of those items, including single members. As an example, “at least one of: a, b, or c” is intended to cover: a, b, c, a-b, a-c, b-c, and a-b-c. As used herein, “or” is intended to be interpreted in the inclusive sense, unless otherwise explicitly indicated. For example, “a or b” may include a only, b only, or a combination of a and b. Similarly, a phrase referring to A “and/or” B may include A only, B only, or a combination of A and B.

As used herein, “based on” is intended to be interpreted in the inclusive sense, unless otherwise explicitly indicated. For example, “based on” may be used interchangeably with “based at least in part on,” “associated with,” or “in accordance with” unless otherwise explicitly indicated. Specifically, unless a phrase refers to “based on only ‘a,’” or the equivalent in context, whatever it is that is “based on ‘a,’” or “based at least in part on ‘a,’” may be based on “a” alone or based on a combination of “a” and one or more other factors, conditions, or information.

The various illustrative components, logic, logical blocks, modules, circuits, operations, and algorithm processes described in connection with the examples disclosed herein may be implemented as electronic hardware, firmware, software, or combinations of hardware, firmware, or software, including the structures disclosed in this specification and the structural equivalents thereof. The interchangeability of hardware, firmware and software has been described generally, in terms of functionality, and illustrated in the various illustrative components, blocks, modules, circuits and processes described above. Whether such functionality is implemented in hardware, firmware or software depends upon the particular application and design constraints imposed on the overall system.

Various modifications to the examples described in this disclosure may be readily apparent to persons having ordinary skill in the art, and the generic principles defined herein may be applied to other examples without departing from the spirit or scope of this disclosure. Thus, the claims are not intended to be limited to the examples shown herein but are to be accorded the widest scope consistent with this disclosure, the principles and the novel features disclosed herein.

Additionally, various features that are described in this specification in the context of separate examples also can be implemented in combination in a single implementation. Conversely, various features that are described in the context of a single implementation also can be implemented in multiple examples separately or in any suitable subcombination. As such, although features may be described above as acting in particular combinations, and even initially claimed as such, one or more features from a claimed combination can in some cases be excised from the combination, and the claimed combination may be directed to a subcombination or variation of a subcombination.

Similarly, while operations are depicted in the drawings in a particular order, this should not be understood as requiring that such operations be performed in the particular order shown or in sequential order, or that all illustrated operations be performed, to achieve desirable results. Further, the drawings may schematically depict one or more example processes in the form of a flowchart or flow diagram. However, other operations that are not depicted can be incorporated in the example processes that are schematically illustrated. For example, one or more additional operations can be performed before, after, simultaneously, or between any of the illustrated operations. In some circumstances, multitasking and parallel processing may be advantageous. Moreover, the separation of various system components in the examples described above should not be understood as requiring such separation in all examples, and it should be understood that the described program components and systems can generally be integrated together in a single software product or packaged into multiple software products.

What is claimed is:

1. An apparatus, comprising:
one or more memories; and
one or more processors coupled to the one or more memories, the one or more processors being configured to, individually or collectively, based at least in part on information stored in the one or more memories:
obtain an input signal representative of a current passing through a first circuit,
apply the input signal to one or more input nodes of a second circuit, different from the first circuit, and configured according to a convolutional neural network model, and
drive one or more output nodes of the second circuit according to a detection by the convolutional neural network model of an arc fault in the current passing through the first circuit, the one or more output nodes driven to:
a first value indicative of an absence of the detection of the arc fault in the current passing through the first circuit, or
a second value indicative of the detection of the arc fault in the current passing through the first circuit.

2. The apparatus of claim 1, where the one or more processors are further configured to configure the convolutional neural network model as a plurality of building blocks, and the one or more processors are further configured to configure each building block as:
a one-dimensional pointwise convolution with one-half of all filters at a first sub-layer, wherein each of the one-half of all filters at the first sub-layer is a 1×1 matrix;
a one-dimensional depthwise convolution with one-half of all filters at a second sub-layer followed by a max pooling at the second sub-layer, wherein each of the one-half of all filters at the second sub-layer is 5×1 matrix; and
a one-dimensional pointwise convolution with all filters at a third sub-layer followed by a one-dimensional stride at the third sub-layer, wherein each of the all filters at the third sub-layer is a 2×1 matrix.

3. The apparatus of claim 1, wherein the convolutional neural network model is a student convolutional neural network model, and the student convolutional neural network model is trained by a pretrained teacher convolutional neural network model.

4. The apparatus of claim 1, wherein the one or more processors are further configured to normalize the input signal prior to the apply the input signal to the one or more input nodes of the second circuit.

5. The apparatus of claim 4, wherein the one or more processors are further configured to normalize the input signal using a min-max normalization technique.

6. The apparatus of claim 4, wherein the one or more processors are further configured to convert the normalized input signal from a time domain signal to a frequency domain signal and apply the frequency domain signal to the one or more input nodes of the second circuit.

7. The apparatus of claim 4, wherein the one or more processors are further configured to subject the normalized input signal to a time domain feature extraction and apply a resultant time domain feature extracted signal to the one or more input nodes of the second circuit.

8. The apparatus of claim 1 further comprising:
one or more current sensors coupled to the one or more processors, each of the one or more current sensors configured to derive a respective voltage waveform representative of the current flowing through the first circuit in a time domain; and
one or more sampling circuits coupled to the one or more current sensors and the one or more processors and configured to sample the respective voltage waveform at a predetermined sampling rate to produce the input signal.

9. The apparatus of claim 1 further comprising:
a switch having an input terminal, an output terminal, and a control terminal, the control terminal coupled to the one or more output nodes of the second circuit and configured to cause the switch to:
impede the current between the input terminal and the output terminal in response to the first value being present at the one or more output nodes of the second circuit, or
pass the current between the input terminal and the output terminal in response to the second value being present at the one or more output nodes of the second circuit.

10. A method at an apparatus, comprising:
obtaining an input signal representative of a current passing through a first circuit;
applying the input signal to one or more input nodes of a second circuit, different from the first circuit, and configured according to a convolutional neural network model; and
driving one or more output nodes of the second circuit according to a detection by the convolutional neural network model of an arc fault in the current passing through the first circuit, the one or more output nodes driven to:
a first value indicative of an absence of the detection of the arc fault in the current passing through the first circuit, or
a second value indicative of the detection of the arc fault in the current passing through the first circuit.

11. The method of claim 10, wherein the convolutional neural network model is configured as a plurality of building blocks, each building block comprising a plurality of sub-layers, and the method further comprises:
configuring a one-dimensional pointwise convolution with one-half of all filters at a first sub-layer, wherein each of the one-half of all filters at the first sub-layer is a 1×1 matrix;
configuring a one-dimensional depthwise convolution with one-half of all filters at a second sub-layer followed by a max pooling at the second sub-layer, wherein each of the one-half of all filters at the second sub-layer is 5×1 matrix; and
configuring a one-dimensional pointwise convolution with all filters at a third sub-layer followed by a one-dimensional stride at the third sub-layer, wherein each of the all filters at the third sub-layer is a 2×1 matrix.

12. The method of claim 10, wherein the convolutional neural network model is a student convolutional neural network model, and the student convolutional neural network model is trained by a pretrained teacher convolutional neural network model.

13. The method of claim 10, further comprising normalizing the input signal prior to the applying the input signal to the one or more input nodes of the second circuit.

14. The method of claim 13, wherein the input signal is normalized using a min-max normalization technique.

15. The method of claim 13, wherein the normalized input signal is converted from a time domain signal to a frequency domain signal and the frequency domain signal is applied to the one or more input nodes of the second circuit.

16. The method of claim 13, wherein the normalized input signal is subjected to time domain feature extraction and a resultant time domain feature extracted signal is applied to the one or more input nodes of the second circuit.

17. The method of claim 10, further comprising:
deriving a respective voltage waveform representative of the current flowing through the first circuit in a time domain; and
sampling the respective voltage waveform at a predetermined sampling rate to produce the input signal.

18. The method of claim 10, wherein the apparatus includes a switch having an input terminal and an output terminal, and in response to driving the one or more output nodes to the second value or the first value, the method further includes:
causing the switch to impede the current between the input terminal and the output terminal, or
causing the switch to pass the current between the input terminal and the output terminal, respectively.

19. An apparatus comprising:
means for obtaining an input signal representative of a current passing through a first circuit;
means for applying the input signal to one or more input nodes of a second circuit, different from the first circuit, and configured according to a convolutional neural network model; and
means for driving one or more output nodes of the second circuit according to a detection by the convolutional neural network model of an arc fault in the current passing through the first circuit, the one or more output nodes driven to:
a first value indicative of an absence of the detection of the arc fault in the current passing through the first circuit, or
a second value indicative of the detection of the arc fault in the current passing through the first circuit.

20. The apparatus of claim 19, wherein the convolutional neural network model is a student convolutional neural network model, and the student convolutional neural network model is trained by a teacher convolutional neural network model.
